(19) United States
(12) Patent Application Publication
(10) Pub. No.: US 2024/0389433 A1
(43) Pub. Date: Nov. 21, 2024

(54) DISPLAY DEVICE

(71) Applicant: Samsung Display Co., Ltd., Yongin-Si (KR)

(72) Inventors: Beom Yeol PARK, Yongin-si (KR); Ki Ho BANG, Yongin-si (KR); Won Suk CHOI, Yongin-si (KR); Yoon Sun CHOI, Yongin-si (KR)

(21) Appl. No.: 18/520,589

(22) Filed: Nov. 28, 2023

(30) Foreign Application Priority Data
May 19, 2023 (KR) 10-2023-0064859

(51) Int. Cl. H10K 59/80; H10K 59/121; H10K 59/131

(52) U.S. Cl. CPC H10K 59/873; H10K 59/1213; H10K 59/131

(57) ABSTRACT

A display device according to an embodiment includes a substrate including a main area including a display area and an inorganic encapsulation area surrounding the display area, and a sub-area extending from the main area, a circuit layer including a semiconductor layer, conductive layers, and insulating layers disposed between the semiconductive layer and the conductive layers, respectively, a light emitting element layer disposed on the circuit layer and including a light emitting element disposed in the display area, and an encapsulation layer covering the light emitting element layer in the display area and including inorganic encapsulation films and an organic encapsulation film disposed between the inorganic encapsulation films, wherein the circuit layer includes a first line extending from the sub-area to the display area through the inorganic encapsulation area, and the first line is covered by an inorganic insulating layer which constitutes the circuit layer.

### CROSS-REFERENCE TO RELATED APPLICATION

This application claims priority to Korean Patent Application No. 10-2023-0064859 filed on May 19, 2023, in the Korean Intellectual Property Office, and all the benefits accruing therefrom under 35 U.S.C. 119, the contents of which in its entirety are herein incorporated by reference.

### BACKGROUND

### 1. Technical Field

Embodiments of the present disclosure relate to a display device.

### 2. Description of the Related Art

The importance of display devices has gradually increased with the development of multimedia. Accordingly, various display devices such as liquid crystal display devices and organic light emitting display devices have been developed.

The display device such as the organic light emitting display device may include an encapsulation layer encapsulating a display area in order to protect pixels. The encapsulation layer may include inorganic encapsulation films directly contacting each other in an inorganic encapsulation area outside the display area. Lines for supplying source voltages or driving signals to the pixels may extend from a non-display area to the display area through the inorganic encapsulation area.

### SUMMARY

Aspects of the present disclosure provide a display device capable of preventing damage to lines passing through an inorganic encapsulation area.

However, aspects of the present disclosure are not restricted to those set forth herein.

The above and other aspects of the present disclosure will become more apparent to one of ordinary skill in the art to which the present disclosure pertains by referencing the detailed description of the present disclosure given below.

According to an aspect of the present disclosure, a display device includes a substrate including a main area which includes a display area and an inorganic encapsulation area surrounding the display area, and a sub-area extending from one side of the main area, a circuit layer including a semiconductor layer, a plurality of conductive layers, and a plurality of insulating layers disposed between the semiconductive layer and the plurality of conductive layers, respectively, a light emitting element layer disposed on the circuit layer and including a light emitting element disposed in the display area, and an encapsulation layer covering the light emitting element layer in the display area and including inorganic encapsulation films and an organic encapsulation film disposed between the inorganic encapsulation films, wherein the circuit layer includes a first line extending from the sub-area to the display area through the inorganic encapsulation area, and, the first line is covered by an inorganic insulating layer which constitutes the circuit layer.

In an embodiment, the display device may further include a dam disposed in a dam area disposed between the display area and the inorganic encapsulation area, and including a planarization film disposed on the first line, and a bank disposed in a bank area outside the inorganic encapsulation area and including the planarization film disposed on the first line.

In an embodiment, the first line may include a first sub-line disposed in the inorganic encapsulation area, a second sub-line disposed in the dam area and connected to one end of the first sub-line, and a third sub-line disposed in the bank area and connected to the other end of the first sub-line.

In an embodiment, the first sub-line may extend from the dam area to the bank area and is connected to the second sub-line in the dam area and the third sub-line in the bank area.

In an embodiment, the first line may include a first line layer, a second line layer and a third line layer overlapping each other in a plan view.

In an embodiment, the first line layer, the second line layer, and the third line layer may be electrically connected to each other through the second sub-line and the third sub-line.

In an embodiment, the first line layer may be in direct contact with at least one of the second line layer and the third line layer.

In an embodiment, the plurality of conductive layers may include a bottom conductive layer disposed between the substrate and the semiconductor layer and a buffer film disposed between the bottom conductive layer and the semiconductor layer, and the first line may further include a fourth line layer disposed on a same plane as the bottom conductive layer.

In an embodiment, the first line layer and the fourth line layer may be electrically connected to each other through the second sub-line and the third sub-line.

In an embodiment, the circuit layer may further include a pixel circuit disposed in the display area and connected to the light emitting element, and the pixel circuit may include a first thin film transistor including a first active layer and a first gate electrode, a second thin film transistor including a second active layer disposed on the first active layer on the first gate electrode and including a semiconductor material different from that of the first active layer, and a second gate electrode, and a capacitor including a capacitor electrode.

In an embodiment, the display device may further include a pixel including the pixel circuit and the light emitting element. The first line may be a power line supplying a first pixel power voltage, a second pixel power voltage, or a bias voltage to the pixel.

In an embodiment, the circuit layer may further include a second line extending from the sub-area to the display area through the inorganic encapsulation area and spaced apart from the first line, and, in the inorganic encapsulation area, the second line may be formed as a single-layer line and is disposed on a same layer as the second gate electrode.

In an embodiment, the second line may be a power line supplying an initialization voltage to the pixel.

In an embodiment, the circuit layer may further include a third line extending from the sub-area to the display area through the inorganic encapsulation area and supplying a driving signal to the pixel, and the third line may be disposed on a same layer as the first gate electrode or a bottom conductive layer disposed between the substrate and the semiconductor layer, and extending across the inorganic encapsulation area to overlap the second line. According to an aspect of the present disclosure, a display device includes a substrate

including a main area including a display area in which a pixel is disposed and an inorganic encapsulation area surrounding the display area, and a sub-area extending from one side of the main area, a circuit layer disposed on the substrate and including a pixel circuit of the pixel and a first power line connected to the pixel and extending from the sub-area to the display area through the inorganic encapsulation area, a light emitting element layer disposed on the circuit layer in the display area and including a light emitting element of the pixel, and an encapsulation layer including inorganic encapsulation films disposed to overlap each other in the display area to cover the light emitting element layer and directly connected to each other in the inorganic encapsulation area, and an organic encapsulation film interposed between the inorganic encapsulation films in the display area, wherein the first power line may be covered by at least one inorganic insulating film which constitutes the circuit layer.

In an embodiment, the circuit layer may include a semiconductor layer, a plurality of conductive layers and a plurality of insulating films disposed on the substrate. The pixel circuit may include a first thin film transistor including a first active layer and a first gate electrode, and a second thin film transistor including a second active layer and a second gate electrode.

In an embodiment, in the inorganic encapsulation area, the first power line may include a first line layer disposed on a same plane as the second gate electrode.

In an embodiment, in the inorganic encapsulation area, the first power line may further include at least one of a second line layer disposed below the first line layer and a third line layer disposed below the second line layer.

In an embodiment, the circuit layer may further include a second power line connected to the pixel and extending from the sub-area to the display area through the inorganic encapsulation area, and, in the inorganic encapsulation area, the second power line may be formed as a single-layer line disposed on the same layer as the second gate electrode.

In an embodiment, the circuit layer may further include a bottom conductive layer disposed between the substrate and the semiconductor layer and a buffer film disposed between the bottom conductive layer and the semiconductor layer, and, in the inorganic encapsulation area, the first power line may further includes a fourth line layer disposed on a same plane as the bottom conductive layer.

A display device according to embodiments may include a line that is positioned below at least one inorganic insulating film provided in a circuit layer in an inorganic encapsulation area in which inorganic encapsulation films are directly contacting each other and is covered by the inorganic insulating film. In some embodiments, the circuit layer may include a first semiconductor layer, a first insulating film, a first conductive layer, a second insulating film, a second conductive layer, a third insulating film, a second semiconductor layer, a fourth insulating film, a third conductive layer, a fifth insulating film, and a fourth conductive layer that are sequentially disposed on a substrate, and the line may be provided at at least the third conductive layer in the inorganic encapsulation area. In some embodiments, the line may be a power line connected to pixels.

According to embodiments, damage to the line passing through the inorganic encapsulation area may be prevented. Accordingly, a defect of the display device may be prevented. In addition, according to embodiments, encapsulation performance of the display device may be improved by blocking a path through which moisture permeation may occur in the inorganic encapsulation area. Accordingly, a section length of the inorganic encapsulation area may be shortened, and a non-display area may be reduced.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating the display device of FIG. 1;

FIG. 3 is a cross-sectional view illustrating an embodiment of a cross section taken along line A-A′ of FIG. 2;

FIG. 4 is a plan view illustrating a display panel according to an embodiment;

FIG. 5 is a circuit diagram illustrating a pixel according to an embodiment;

FIG. 6 is a circuit diagram illustrating a pixel according to an embodiment;

FIG. 7 is a cross-sectional view illustrating the display panel according to an embodiment;

FIG. 8 is a plan view illustrating area B of FIG. 4;

FIG. 9 is a plan view illustrating area B of FIG. 4;

FIG. 10 is a plan view illustrating a first power line according to an embodiment;

FIG. 11 is a cross-sectional view illustrating an embodiment of a cross section taken along line C-C′ of FIG. 9;

FIG. 12 is a cross-sectional view illustrating an embodiment of a cross section taken along line C-C′ of FIG. 9;

FIG. 13 is a plan view illustrating a first power line according to an embodiment;

FIG. 14 is a cross-sectional view illustrating an embodiment of a cross section taken along line C-C′ of FIG. 9;

FIG. 15 is a plan view illustrating a first power line according to an embodiment;

FIG. 16 is a cross-sectional view illustrating an embodiment of a cross section taken along line C-C′ of FIG. 9;

FIG. 17 is a plan view illustrating a second power line according to an embodiment; and

FIG. 18 is a cross-sectional view illustrating an embodiment of a cross section taken along line D-D′ of FIG. 9.

### DETAILED DESCRIPTION OF THE EMBODIMENTS

The present inventive concept will now be described more fully hereinafter with reference to the accompanying drawings, in which preferred embodiments of the inventive concept are shown. This inventive concept may, however, be embodied in different forms and should not be construed as limited to the embodiments set forth herein. Rather, these embodiments are provided so that this disclosure will be thorough and complete, and will filly convey the scope of the inventive concept to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present inventive concept. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

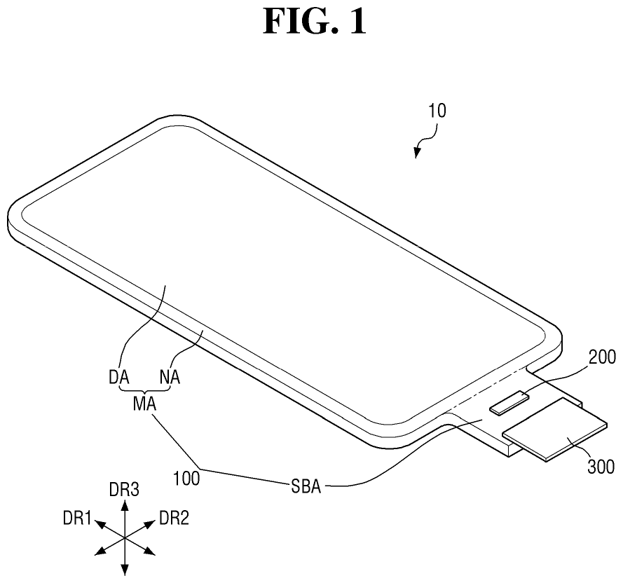

FIG. 1 is a perspective view illustrating a display device 10 according to an embodiment.

Referring to FIG. 1, a display device 10 is a device that displays a moving image or a still image, and may be used as a display screen of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

The display device 10 may be a light emitting display device such as an organic light emitting display device including organic light emitting diodes, a quantum dot light emitting display device including quantum dot light emitting layers, an inorganic light emitting display device including inorganic semiconductors, or a micro light emitting display device using micro or nano light emitting diodes (micro LEDs or nano LEDs). Hereinafter, an embodiment in which the display device 10 is an organic light emitting display device has been described, but a type of the display device 10 is not limited thereto.

In an embodiment, the display device 10 may be formed to be flat. For example, the display device 10 may have a flat surface in an area defined by a first direction DR1 and a second direction DR2 and may have a predetermined thickness (or height) in a third direction DR3. In another embodiment, the display device 10 may include curved portions in at least a portion thereof including an edge area or the like. In addition, the display device 10 may be flexibly formed to be curved, bent, folded, or rolled.

In an embodiment, based on an image display surface of the display device 10, the first direction DR1 may be a longitudinal direction, a column direction, or a vertical direction, and the second direction DR2 is a direction crossing the first direction DR1 and may be, for example, a transverse direction, a row direction, or a horizontal direction. The third direction DR3 may be a thickness direction or a height direction of the display device 10.

The display device 10 may include a display panel 100, a driving circuit 200, and a circuit board 300.

The display panel 100 may include a main area MA including a display area DA on which an image is displayed and a sub-area SBA positioned on one side of the main area MA.

The main area MA may include the display area DA and a non-display area NA positioned around the display area DA. The display area DA may be positioned at the center of the main area MA, and may occupy most of the main area MA. The non-display area NA may be positioned at an edge of the main area MA, and may be in contact with the sub-area SBA.

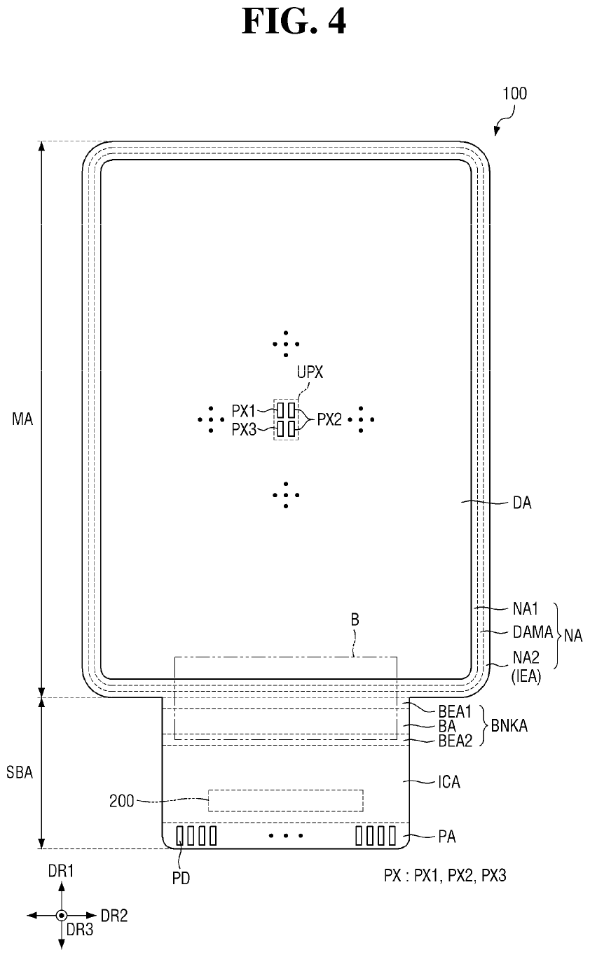

The display area DA is an area in which pixels (e.g., pixels PX of FIG. 4) are arranged, and may be an area in which an image is displayed by the pixels PX. In an embodiment, the display area DA may further include sensing patterns (e.g., touch electrodes) for sensing a touch input or the like, and may include a sensing area sensing the touch input by the sensing patterns.

In an embodiment, the display area DA may have a substantially rectangular shape, in a plan view, which include long sides in the first direction DR1 and short sides in the second direction DR2. A corner portion where the long side and the short side of the display area DA meet may be rounded or right-angled. A shape of the display area DA may be variously changed according to embodiments. For example, the display area DA may also be formed in other polygonal shapes other than the rectangular shape, a circular shape, an elliptical shape, or the like.

The non-display area NA may be positioned adjacent to the display area DA. The non-display area NA may surround the display area DA. The non-display area NA may include a dam area, an inorganic encapsulation area, and the like. In an embodiment, an embedded circuit may be disposed in the non-display area NA. For example, an embedded circuit including a scan driving circuit or the like may be disposed in the non-display area NA positioned on one side (e.g., the left side or the right side) or both sides of the display area DA.

The sub-area SBA may be positioned on one side of the main area MA. For example, the sub-area SBA may protrude from one side of the main area MA in the first direction DR1. As an example, the sub-area SBA may protrude from a lower end of the main area MA in the first direction DR1. In an embodiment, the sub-area SBA may have a width narrower than that of the main area MA. For example, based on the second direction DR2, the sub-area SBA may have a width narrower than that of the main area MA.

Lines and pads may be provided in the sub-area SBA. For example, lines and pads connected to the pixels and/or the embedded circuit positioned in the main area MA and the driving circuit 200 and/or circuit board 300 positioned in the sub-area SBA may be disposed in the sub-area SBA. In describing embodiments, the term “connection” may include the meaning of an electrical connection and/or a physical connection.

In an embodiment, the driving circuit 200 (e.g., a display driving circuit) may be mounted in the sub-area SBA. The circuit board 300 may be disposed on a portion of the sub-area SBA.

The driving circuit 200 may include a data driving circuit for driving the pixels. In an embodiment, the driving circuit 200 may be provided as an integrated circuit (IC) and mounted in the sub-area SBA. In another embodiment, the driving circuit 200 may be provided on the circuit board 300 on the sub-area SBA or may be provided on another circuit board connected to the display panel 100 through the circuit board 300.

The circuit board 300 may be disposed on a portion of the sub-area SBA. For example, the circuit board 300 may be connected to pads positioned at a portion (e.g., a lower edge) of the sub-area SBA, and may supply or transfer source voltages and driving signals for driving the display panel 100 to the display panel 100. For example, the circuit board 300 may supply input image data (e.g., digital image data), driving signals including timing signals, and driving voltages to the display panel 100. The circuit board 300 may be a flexible printed circuit board (FPCB), a printed circuit board (PCB), or a flexible film such as a chip on film (COF), but the configuration of the circuit board is not limited thereto.

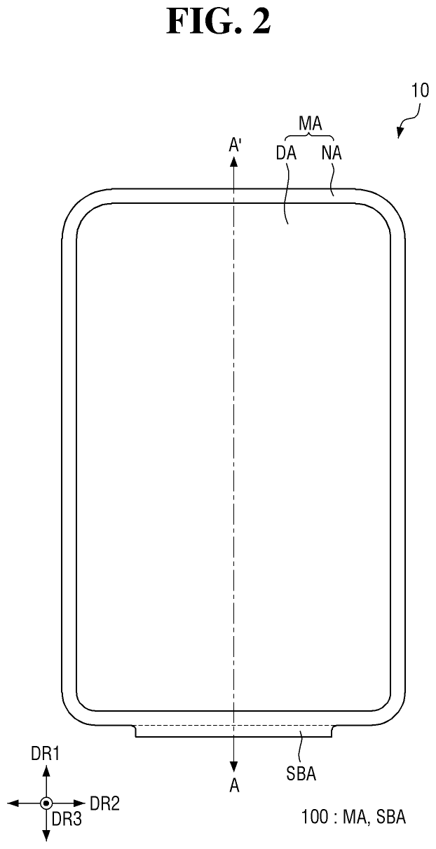

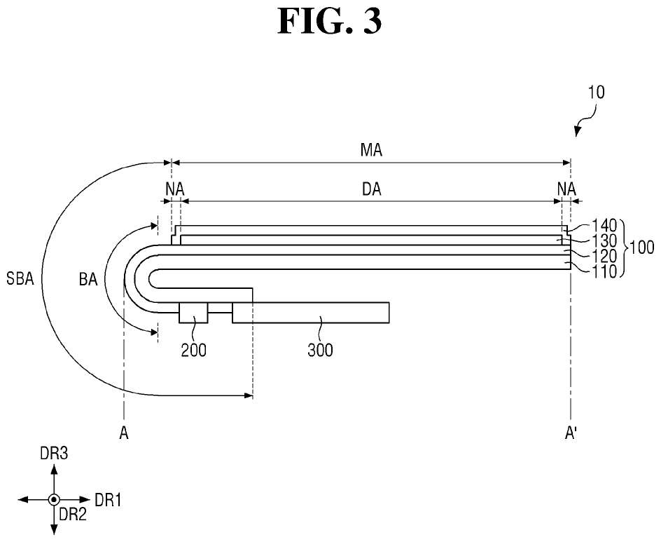

FIG. 2 is a plan view illustrating the display device 10 of FIG. 1. FIG. 3 is a cross-sectional view illustrating an embodiment of a cross section taken along line A-A′ of FIG. 2.

FIG. 1 illustrates a state in which the display device 10 is not bent, and FIGS. 2 and 3 illustrate a state in which the display device 10 is bent in the sub-area SBA. For example, FIG. 1 illustrates a state in which the sub-area SBA is unbent, and FIGS. 2 and 3 illustrate a state in which a portion of the sub-area SBA is bent.

Referring to FIGS. 2 and 3, the display panel 100 may include a substrate 110 including a main area MA and a sub-area SBA and a circuit layer 120, a light emitting element layer 130, and an encapsulation layer 140 that are sequentially disposed on the substrate 110. The circuit layer 120 may be positioned in the main area MA and the sub-area SBA on the substrate 110. The light emitting device layer 130 and the encapsulation layer 140 may be positioned on portions of the substrate 110 and the circuit layer 120. For example, the light emitting device layer 130 and the encapsulation layer 140 may be positioned in the main area MA.

In an embodiment, the display device 10 may further include additional components disposed on the display panel 100. For example, the display device 10 further includes at least one of a sensor layer (e.g., a touch sensor layer), a polarization layer, a color filter layer, and a protective layer (e.g., a window) disposed on the encapsulation layer 140. Each of the sensor layer, the polarization layer, the color filter layer, and/or the protective layer may be manufactured integrally with the display panel 100 or may be manufactured separately from the display panel 100 and attached to the display panel 100 via an adhesive layer or the like.

The substrate 110 may include an insulating material such as a polymer resin. For example, the substrate 110 may be made of polyimide or other insulating materials. The substrate 110 may be a flexible substrate that may be deformed, for example, bent, folded, and rolled. Alternatively, the substrate 110 may include an insulating material such as glass.

The circuit layer 120 may include pixel circuits and signal lines. For example, the circuit layer 120 may include circuit elements (e.g., transistors and a capacitor) constituting a pixel circuit of each of the pixels and signal lines connected to the pixels. In an embodiment, the circuit layer 120 may further include circuit elements constituting the embedded circuit such as the scan driving circuit and signal lines connected to the embedded circuit.

The light emitting element layer 130 may include light emitting elements provided in emission areas of the pixels. For example, each pixel may include at least one light emitting element and a pixel circuit connected to the light emitting element. Each pixel may be positioned in each pixel area including the emission area in which the light emitting element is disposed and a pixel circuit area in which the pixel circuit is disposed. The emission area and the pixel circuit area of each pixel may overlap each other, but the configuration of the emission area and the pixel circuit area are not limited thereto.

In describing embodiments, the circuit layer 120 and the light emitting element layer 130 have been separately described, but embodiments are not limited thereto. For example, the circuit layer 120 and the light emitting element layer 130 may be integrated with each other.

The encapsulation layer 140 may cover the light emitting element layer 130 and extend to the non-display area NA to be in contact with the circuit layer 120. In an embodiment, the encapsulation layer 140 may have a multilayer structure including at least two inorganic encapsulation films overlapping each other and at least one organic encapsulation film interposed between the inorganic encapsulation films.

In an embodiment, the display panel 100 may be bent in a bending area BA. The bending area BA may be a portion of the sub-area SBA and may be spaced apart from the main area MA.

The substrate 110 and the circuit layer 120 may be bent in the bending area BA corresponding to a partial section of the sub-area SBA. Accordingly, a bezel area recognized as the non-display area NA by a user may be reduced or minimized.

FIG. 4 is a plan view illustrating a display panel 100 according to an embodiment. FIG. 4 illustrates a state in which the display panel 100 is not bent.

Referring to FIG. 4, the display panel 100 may include a main area MA including a display area DA and a non-display area NA, and a sub-area SBA including a bank area BNKA, a driving circuit mounting area ICA, a pad area PA, and the like.

The display area DA may be an area in which pixels PX are arranged. The pixels PX and signal lines (or portions of the lines) connected to the pixels PX may be disposed in the display area DA.

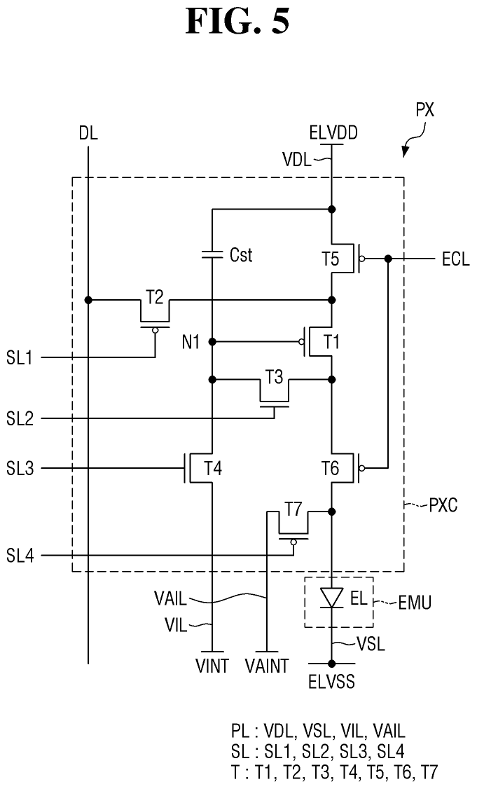

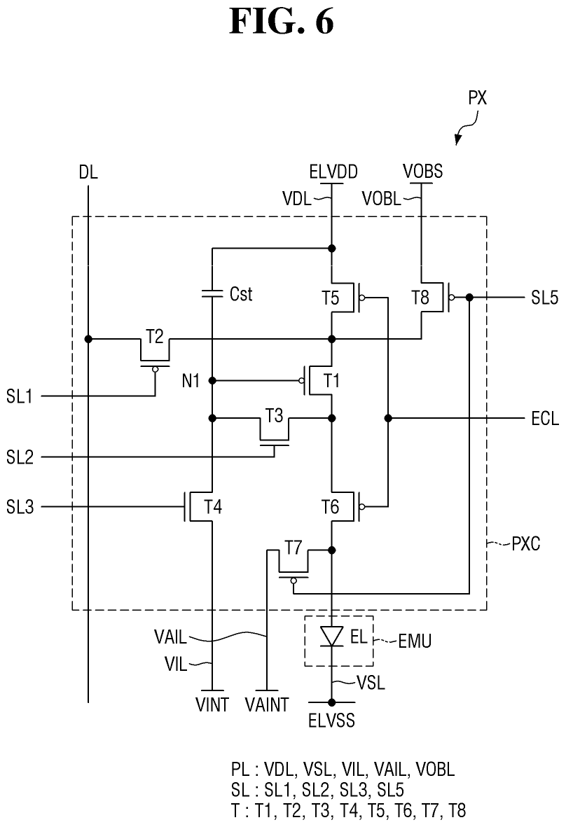

The pixels PX may include the circuit layer 120 and the light emitting element layer 130 of the display panel 100. As an example, each pixel PX may include a pixel circuit (e.g., a pixel circuit PXC of FIG. 5 or 6) including circuit elements provided in the circuit layer 120 and a light emitting element (e.g., a light emitting element EL of FIG. 5 or 6) provided in the light emitting element layer 130.

The pixels PX may include at least two color pixels PX emitting light of different colors. For example, the pixels PX may include first color pixels PX1 emitting light of a first color (e.g., red light), second color pixels PX2 emitting light of a second color (e.g., green light), and third color pixels PX3 emitting light of a third color (e.g., blue light).

At least one first color pixel PX1, at least one second color pixel PX2, and at least one third color pixel PX3 disposed adjacent to each other may constitute a unit pixel UPX. For example, one first color pixel PX1, two second color pixels PX2, and one third color pixel PX3 disposed adjacent to each other may constitute one unit pixel UPX. Each unit pixel UPX may emit light of various colors including white light by mixing colors of light emitted from the pixels PX constituting each unit pixel UPX. In an embodiment, the first color pixels PX1 and the third color pixels PX3 may be alternately arranged in the first direction DR1 and/or the second direction DR2, and the second color pixels PX2 may be arranged in the first direction DR1. Types, shapes, arrangement structures, and the like, of the pixels PX may be variously changed according to embodiments. In addition, types, the number, ratios, arrangement structures, and the like of the pixels PX constituting each unit pixel UPX may also be variously changed according to embodiments.

The encapsulation layer 140 may be disposed on the pixels PX. For example, the encapsulation layer 140 may be provided in at least the display area DA to cover the pixels PX, and a portion of the encapsulation layer 140 may extend to the non-display area NA.

The signal lines may be provided in the circuit layer 120 and may be positioned in the display area DA and the non-display area NA. In addition, the lines may also be positioned in the sub-area SBA. For example, the lines may extend from the sub-area SBA to the display area DA through the non-display area NA.

The non-display area NA may be positioned around the display area DA. For example, the non-display area NA may be an edge area of the main area MA positioned outside the display area DA.

The non-display area NA may include a dam area DAMA spaced apart from the display area DA, a first non-display area NA1 positioned between the display area DA and the dam area DAMA, and a second non-display area NA2 positioned outside the dam area DAMA. The dam area DAMA may be an area in which a dam surrounding the display area DA is disposed. The second non-display area NA2 may include an inorganic encapsulation area IEA (also referred to as a “bonding area”) in which the inorganic encapsulation films of the encapsulation layer 140 are directly contacting each other.

The sub-area SBA may include the bank area BNKA, the driving circuit mounting area ICA, and the pad area PA that are sequentially disposed on one side of the main area MA. Signal lines (or portions of lines), a bank, and pads PD may be disposed in the sub-area SBA. At least some of the signal lines may extend to the main area MA to be connected to the pixels PX.

The bank area BNKA may be an area in which a bank including at least one organic film is disposed. In an embodiment, the bank area BNKA may include the bending area BA. For example, the bank area BNKA may include the bending area BA spaced apart from the main area MA, and a first edge area BEA1 and a second edge area BEA2 respectively positioned on each side of the bending area BA in the first direction DR1. The bank may be provided in the bending area BA and its surrounding areas (e.g., the first edge area BEA1 and the second edge area BEA2 of the bank area BNKA) to cover signal lines passing through the bending area BA. The display panel 100 is bent in the bending area BA such that a portion of the sub-area SBA may be positioned behind the main area MA.

The driving circuit mounting area ICA may be an area in which the driving circuit 200 is mounted. Pads for connecting at least some signal lines to the driving circuit 200 may be disposed in the driving circuit mounting area ICA. For example, input pads for connecting the driving circuit 200 to specific pads (e.g., data input pads) of the pad area PA and output pads for connecting the driving circuit 200 to the pixels PX may be disposed in the driving circuit mounting area ICA.

In some embodiments, the driving circuit 200 may not be mounted on the display panel 100. In this case, the display panel 100 may not include the driving circuit mounting area ICA, and only the signal lines may be disposed in an area between the bank area BNKA and the pad area PA.

The pad area PA may be an area in which pads PD for connecting the display panel 100 and/or the driving circuit 200 to the circuit board 300 or the like are disposed. The circuit board 300 may be connected to the pad area PA.

A plurality of pads PD including power pads and signal pads connected to the pixels PX, the driving circuit 200, the embedded circuit, and the like, may be disposed in the pad area PA. Source voltages for driving the pixels PX, the driving circuit 200, the embedded circuit, and the like may be supplied to the power pads. Driving signals and/or image data for driving the pixels PX, the driving circuit 200, the embedded circuit, and the like may be supplied to the signal pads. Types, positions, an arrangement order, the number, and the like, of the pads PD may be variously changed according to embodiments.

FIG. 5 is a circuit diagram illustrating a pixel PX according to an embodiment. FIG. 6 is a circuit diagram illustrating a pixel PX according to an embodiment. For example, FIGS. 5 and 6 illustrate different embodiments of a pixel circuit PXC and signal lines connected to the pixel circuit PXC. A configuration of the pixel circuit PXC and types and the number of lines connected to the pixel circuit PXC may be variously changed according to embodiments.

In FIG. 5, an embodiment in which each pixel circuit PXC includes first to seventh transistors T1 to T7 is illustrated. In an embodiment, scan lines SL connected to the pixel PX of FIG. 5 may include a first scan line SL1, a second scan line SL2, a third scan line SL3, and a fourth scan line SL4, and power lines PL connected to the pixel PX of FIG. 5 may include a first pixel power line VDL, a second pixel power line VSL, a first initialization power line VIL, and a second initialization power line VAIL. The pixel PX of FIG. 5 may be further connected to an emission control line ECL.

In FIG. 6, an embodiment in which each pixel circuit PXC includes first to eighth transistors T1 to T8 is illustrated. In an embodiment, scan lines SL connected to the pixel PX of FIG. 6 may include a first scan line SL1, a second scan line SL2, a third scan line SL3, and a fifth scan line SL5, and power lines PL connected to the pixel PX of FIG. 5 may include a first pixel power line VDL, a second pixel power line VSL, a first initialization power line

VIL, a second initialization power line VAIL, and a bias power line VOBL. The pixel PX of FIG. 6 may be further connected to an emission control line ECL.

Referring to FIG. 5, the pixel PX may include a light emitting unit EMU including at least one light emitting element EL and a pixel circuit PXC (also referred to as a “pixel driving unit”) connected to the light emitting unit EMU.

The light emitting element EL may be connected between the second pixel power line VSL to which a second pixel power voltage ELVSS is applied and the pixel circuit PXC. In an embodiment, the second pixel power voltage ELVSS may be a low potential pixel driving voltage. The light emitting element EL is a light source of the pixel PX, and may emit light in response to a driving current supplied from the pixel circuit PXC.

The light emitting element EL may be an organic light emitting diode, but the configuration of the light emitting element EL is not limited thereto. For example, the light emitting element EL may be an inorganic light emitting element, a quantum dot light emitting element, or other types of light emitting elements.

The pixel circuit PXC may control a light emitting timing and luminance of the light emitting element EL by controlling the driving current supplied to the light emitting element EL. The pixel circuit PXC may include at least one pixel transistor and a capacitor Cst. In an embodiment, the pixel circuit PXC may include pixel transistors including first to seventh transistors T1 to T7.

The first transistor T1 may include a gate electrode connected to a first node N1, a first electrode connected to the first pixel power line VDL via the fifth transistor T5, and a second electrode connected to the light emitting unit EMU via the sixth transistor T6. One of the first electrode and the second electrode may be a source electrode, and the other of the first electrode and the second electrode may be a drain electrode. The first transistor T1 may control a source-drain current (hereinafter referred to as a “driving current”) flowing between the first electrode and the second electrode according to a voltage applied to the gate electrode (e.g., a voltage of the first node N1 corresponding to a voltage of a data signal). For example, the first transistor T1 may be a driving transistor of the pixel PX.

The second transistor T2 may include a gate electrode connected to the first scan line SL1, a first electrode connected to a data line DL, and a second electrode connected to the first electrode of the first transistor T1. The second transistor T2 may be turned on in response to a first scan signal supplied to the first scan line SL1 to connect the first electrode of the first transistor T1 to the data line DL. When the second transistor T2 is turned on, a voltage of a data signal supplied to the data line DL may be applied to the first electrode of the first transistor T1.

The third transistor T3 may include a gate electrode connected to the second scan line SL2, a first electrode connected to the second electrode of the first transistor T1, and a second electrode connected to the gate electrode of the first transistor T1 (or the first node N1). The third transistor T3 may be turned on in response to a second scan signal supplied to the second scan line SL2 to connect the gate electrode and the second electrode of the first transistor T1 to each other. When the third transistor T3 is turned on, the first transistor T1 may be driven as a diode.

The fourth transistor T4 may include a gate electrode connected to the third scan line SL3, a first electrode connected to the gate electrode of the first transistor T1, and a second electrode connected to the first initialization power line VIL. The fourth transistor T4 may be turned on in response to a third scan signal supplied to the third scan line SL3 to connect the gate electrode of the first transistor T1 to the first initialization power line VIL. When the fourth transistor T4 is turned on, a first initialization voltage VINT (e.g., a gate initialization voltage) of the first initialization power line VIL may be applied to the gate electrode of the first transistor T1.

The fifth transistor T5 may include a gate electrode connected to the emission control line ECL, a first electrode connected to the first pixel power line VDL, and a second electrode connected to the first electrode of the first transistor T1. The fifth transistor T5 may be turned on in response to an emission control signal supplied to the emission control line ECL to connect the first electrode of the first transistor T1 to the first pixel power line VDL to which a first pixel power voltage ELVDD is applied. When the fifth transistor T5 is turned on, the first pixel power voltage ELVDD may be applied to the first electrode of the first transistor T1. In an embodiment, the first pixel power voltage ELVDD may be a high potential pixel driving voltage.

The sixth transistor T6 may include a gate electrode connected to the emission control line ECL, a first electrode connected to the second electrode of the first transistor T1, and a second electrode connected to the light emitting element EL. The sixth transistor T6 may be turned on in response to an emission control signal supplied to the emission control line ECL to connect the first transistor T1 to the light emitting element EL. When both the fifth transistor T5 and the sixth transistor T6 are turned on, the driving current having a magnitude corresponding to the voltage of the gate electrode of the first transistor T1 may flow to the light emitting element EL.

The seventh transistor T7 may include a gate electrode connected to the fourth scan line SL4, a first electrode connected to an anode electrode of the light emitting element EL, and a second electrode connected to the second initialization power line VIL2. The seventh transistor T7 may be turned on in response to a fourth scan signal supplied to the fourth scan line SL4 to connect the anode electrode of the light emitting element EL to the second initialization power line VAIL. The fourth scan signal may be a signal that is the same as or different from the first scan signal. When the fourth transistor T7 is turned on, a second initialization voltage VAINT (e.g., an anode initialization voltage) of the second initialization power line VAIL may be applied to the anode electrode of the light emitting element EL.

The capacitor Cst may be connected between the gate electrode of the first transistor T1 and the first pixel power line VDL. The capacitor Cst may be charged with a voltage corresponding to the voltage of the data signal applied to the gate electrode of the first transistor T1.

An active layer (e.g., a semiconductor pattern including a channel region) of each of the pixel transistors (e.g., the first to seventh transistors T1 to T7) may include one semiconductor material of polysilicon, amorphous silicon, and an oxide semiconductor. In an embodiment, some and the others of the pixel transistors may be formed as different conductivity-type transistors. In addition, some and the others of the pixel transistors may include different types of semiconductor materials.

For example, the first, second, fifth, sixth, and seventh transistors T1, T2, T5, T6, and T7 may be formed as P-type transistors (e.g., P-type metal oxide semiconductor field effect transistor (MOSFETs)) including the respective active layers made of the polysilicon, and the third and fourth transistors T3 and T4 may be formed as N-type transistors (e.g., N-type MOSFETs) including the respective active layers made of the oxide semiconductor. In an embodiment, the transistors including the respective active layers made of the polysilicon and the transistors including the respective active layers made of the oxide semiconductor may be disposed on different layers within the circuit layer 120.

Referring to FIG. 6, the pixel circuit PXC may further include an eighth transistor T8. The eighth transistor T8 may include a gate electrode connected to the fifth scan line SL5, a first electrode connected to the bias power line VOBL, and a second electrode connected to the first electrode of the first transistor T1. The eighth transistor T8 may be turned on in response to a fifth scan signal supplied to the fifth scan line SL5 to connect the first electrode of the first transistor T1 to the bias power line VOBL. When the eighth transistor T8 is turned on, a bias voltage VOBS supplied to the bias power line VOBL may be applied to the first electrode of the first transistor T1. In an embodiment, the bias voltage VOBS may have a voltage level suitable for compensating for hysteresis characteristics of the first transistor T1. As the eighth transistor T8 is turned on, the first electrode of the first transistor T1 may be initialized to the bias voltage VOBS.

In an embodiment of FIG. 6, the gate electrode of the seventh transistor T7 may be connected to the fifth scan line SL5. Accordingly, the seventh transistor T7 may be turned on in response to the fifth scan signal supplied to the fifth scan line SL5 to connect the anode electrode of the light emitting element EL to the second initialization power line VAIL.

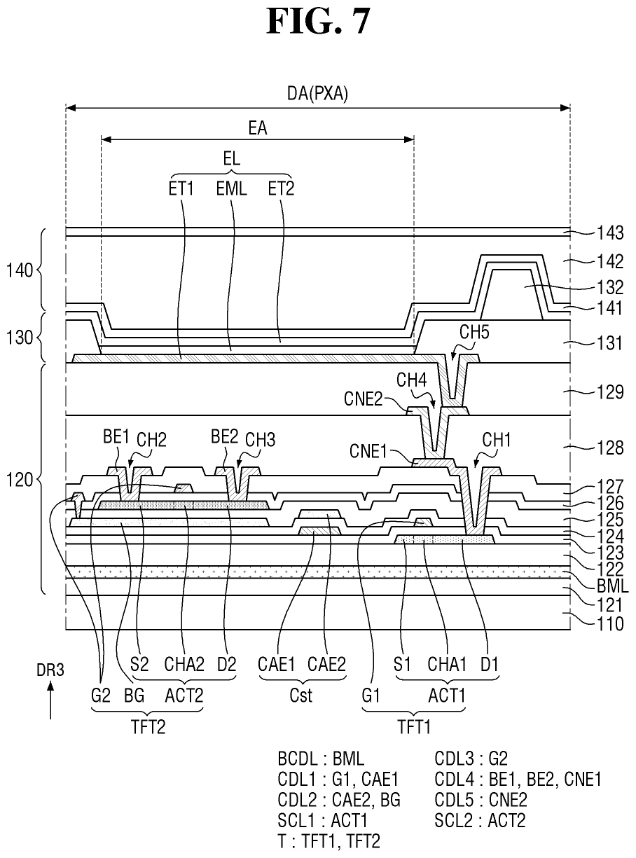

FIG. 7 is a cross-sectional view illustrating the display panel 100 according to an embodiment. For example, FIG. 7 schematically illustrates a cross section of a portion of the display area DA corresponding to a pixel area PXA in which one pixel PX is positioned.

Referring to FIG. 7, the display panel 100 may include the substrate 110, and the circuit layer 120, the light emitting element layer 130, and the encapsulation layer 140 that are disposed on the substrate 110. The circuit layer 120, the light emitting element layer 130, and the encapsulation layer 140 may be sequentially disposed or stacked on the substrate 110 along the third direction DR3.

The substrate 110 may be made of a material having flexible characteristics so as to be able to be bent, folded, or rolled. The substrate 110 may be made of an insulating material such as a polymer resin. As an example, the substrate 110 may be made of polyimide.

The circuit layer 120 may include pixel circuits PXC and signal lines. For example, the circuit layer 120 may include circuit elements (e.g., pixel transistors and a capacitor Cst) constituting the pixel circuit PXC of each of the pixels PX and signal lines (e.g., various power lines such as the first pixel power line VDL, the first initialization power line VIL, the second initialization power line VAIL and the second pixel power line VSL and signal lines including scan lines SL (SL1, SL2, SL3 and SL4), emission control lines ECL, and data lines DL) connected to the pixels PX.

In FIG. 7, only a first thin film transistor TFT1 (also referred to as a “first pixel transistor”), a second thin film transistor TFT2 (also referred to as a “second pixel transistor”), and a capacitor Cst that are provided in the pixel area PXA of each pixel PX in the circuit layer 120 are illustrated. The first thin film transistor TFT1 may be first-type transistors (e.g., P-type transistors) including a first semiconductor material (e.g., polysilicon). For example, the first thin film transistor TFT1 may be one of the first, second, fifth, sixth, seventh, and/or eighth transistors T1, T2, T5, T6, T7, and/or T8. In FIG. 7, one transistor (for example, the sixth transistor T6 of FIG. 5 or 6) connected to a light emitting element EL through at least one connection electrode (e.g., a first connection electrode CNE1 and a second connection electrode CNE2) among the first-type transistors has been illustrated as the first thin film transistor TFT1. The second thin film transistor TFT2 may be second-type transistors (e.g., N-type transistors) including a second semiconductor material (e.g., an oxide semiconductor). For example, the second thin film transistor TFT2 may be one of the third and fourth transistors T3 and T4.

Cross-sections of the pixels PX may be variously changed according to types, structures, and the like of the respective pixels PX and the display panel 100 including the respective pixels PX. For example, positions, order of formation, and the like of the first thin film transistor TFT1, the second thin film transistor TFT2, and the capacitor Cst may be changed according to embodiments.

The circuit layer 120 may include semiconductor layers and conductive layers for forming the circuit elements, the signal lines, and the like, and insulating films disposed between and/or around the conductive layers and the semiconductor layer. For example, the circuit layer 120 may include a first semiconductor layer SCL1 (e.g., a polysilicon semiconductor layer), a first insulating film 123 (e.g., a first gate insulating film), a first conductive layer CDL1 (e.g., a first gate conductive layer), a second insulating film 124 (e.g., a second gate insulating film), a second conductive layer CDL2 (e.g., a second gate conductive layer), a third insulating film 125 (e.g., a first interlayer insulating film), a second semiconductor layer SCL2 (e.g., an oxide semiconductor layer), a fourth insulating film 126 (e.g., a third gate insulating film), a third conductive layer CDL3 (e.g., a third gate conductive layer), a fifth insulating film 127 (e.g., a second interlayer insulating film), a fourth conductive layer (CDL4) (e.g., a first source-drain conductive layer and a first connection electrode CNE1), and a sixth insulating film 128 (e.g., a first via film or a first planarization film) that are sequentially disposed on the substrate 110 along the third direction DR3. In an embodiment, the circuit layer 120 may further include a fifth conductive layer CDL5 (e.g., a second connection electrode CNE2) and a seventh insulating film 129 (e.g., a second via film or a second planarization film) that are sequentially disposed on the sixth insulating film 128. In an embodiment, the circuit layer 120 may further include a bottom conductive layer BCDL disposed between the substrate 110 and the first semiconductor layer SCL1, a barrier film 121 disposed between the substrate 110 and the bottom conductive layer BCDL, and a buffer film 122 disposed between the bottom conductive layer BCDL and the first semiconductor layer SCL1.

The barrier film 121 may be disposed on the substrate 110. The barrier film 121 may protect elements disposed in the circuit layer 120 and the light emitting element layer 130 from moisture permeating through the substrate 110 which is vulnerable to moisture permeation. The barrier film 121 may include at least one inorganic film including an inorganic insulating material (e.g., silicon nitride, silicon oxide, silicon oxynitride, titanium oxide, aluminum oxide, or other inorganic insulating materials). A material of the barrier film 121 may be variously changed according to embodiments.

The bottom conductive layer BCDL may be disposed on the barrier film 121. The bottom conductive layer BCDL may include a bottom metal layer BML overlapping an active layer (e.g., a first active layer ACT1 and/or a second active layer ACT2) of at least one pixel transistor and/or at least one signal line (or a portion of the at least one signal line). It has been illustrated in FIG. 7 that the bottom metal layer BML is entirely disposed in the pixel area PXA, but embodiments are not limited thereto. For example, the bottom metal layer BML may also be patterned in an appropriate size and/or shape as needed and positioned only in a portion of the pixel area PXA. As an example, the bottom metal layer BML may also be positioned only in a portion of the pixel area PXA so as to be positioned below the first transistor T1 illustrated in FIGS. 5 and 6. In an embodiment, the bottom metal layer BML may also be utilized as a light blocking pattern, a back-gate electrode of at least one pixel transistor, and the like.

The buffer film 122 may be disposed on the bottom conductive layer BCDL to cover the bottom conductive layer BCDL. The buffer film 122 may include at least one inorganic film including an inorganic insulating material.

The first thin film transistor TFT1, the second thin film transistor TFT2, and the capacitor Cst may be disposed on one surface of the substrate 110 including the buffer film 122. The first thin film transistor TFT1 may include the first active layer ACT1 and a first gate electrode G1. The second thin film transistor TFT2 may include the second active layer ACT2 and a second gate electrode G2. In an embodiment, the second thin film transistor TFT2 may include a back-gate electrode BG. The capacitor Cst may include a first capacitor electrode CAE1 and a second capacitor electrode CAE2.

Specifically, the first semiconductor layer SCL1 may be disposed on the buffer film 122. The first semiconductor layer SCL1 may include the first active layer ACT1 of the first thin film transistor TFT1. For example, the first semiconductor layer SCL1 may include the first active layer ACT1 of each of the first, second, fifth, sixth, seventh, and/or eighth transistors T1, T2, T5, T6, T7, and/or T8.

The first active layer ACT1 may be disposed in the first semiconductor layer SCL1 and may include the first semiconductor material (e.g., the polysilicon). The first active layer ACT1 may include a first channel region CHA1, a first source region S1, and a first drain region D1. The first channel region CHA1 may overlap the first gate electrode G1 in the third direction DR3. The first source region S1 may be disposed on one side of the first channel region CHA1, and the first drain region D1 may be disposed on the other side of the first channel region CHA1. The first source region S1 and the first drain region D1 may be regions doped with ions or impurities to give conductivity to the first active layer ACT1. In an embodiment, the first source region S1 may be a source electrode of the first thin film transistor TFT1. In another embodiment, the first thin film transistor TFT1 may include a separate source electrode connected to the first source region S1. In an embodiment, the first drain region D1 may be a drain electrode of the first thin film transistor TFT1. In another embodiment, the first thin film transistor TFT1 may include a separate drain electrode connected to the first drain region D1.

The first insulating film 123 may be disposed on the first semiconductor layer SCL1. The first insulating film 123 may cover the first semiconductor layer SCL1.

The first conductive layer CDL1 may be disposed on the first insulating film 123. The first conductive layer CDL1 may include the first gate electrode G1 of the first thin film transistor TFT1. The first gate electrode G1 may be disposed in the first conductive layer CDL1 overlapping a portion (e.g., the first channel region CHA1) of the first active layer ACT1. In an embodiment, the first conductive layer CDL1 may further include at least one signal line (or a portion of the at least one signal line), a conductive pattern (e.g., a bridge pattern), and/or a capacitor electrode. As an example, the first conductive layer CDL1 may further include the first capacitor electrode CAE1 of the capacitor Cst.

In an embodiment, the first capacitor electrode CAE1 may be formed integrally with a gate electrode of at least one first thin film transistor TFT1. For example, the first capacitor electrode CAE1 may be formed integrally with the gate electrode of the first transistor T1 illustrated in FIGS. 5 and 6. As an example, the first capacitor electrode CAE1 and the gate electrode of the first transistor T1 may be formed as one conductive pattern, and the second capacitor electrode CAE2 may be disposed to overlap the conductive pattern.

The second insulating film 124 may be disposed on the first conductive layer CDL1. The second insulating film 124 may cover the first conductive layer CDL1.

The second conductive layer CDL2 may be disposed on the second insulating film 124. The second conductive layer CDL2 may include one electrode, for example, the second capacitor electrode CAE2 of the capacitor Cst. In an embodiment, the second conductive layer CDL2 may further include at least one electrode, at least one signal line (or a portion of the at least one signal line), and/or a conductive pattern (e.g., a bridge pattern). For example, the second conductive layer CDL2 may further include the back-gate electrode BG connected to the second gate electrode G2 of the second thin film transistor TFT2. The third insulating film 125 may be disposed on the second conductive layer CDL2. The third insulating film 125 may cover the second conductive layer CDL2.

The second semiconductor layer SCL2 may be disposed on the third insulating film 125. The second semiconductor layer SCL2 may include the second active layer ACT2 of the second thin film transistor TFT2. For example, the second semiconductor layer SCL2 may include the second active layer ACT2 of each of the third and fourth transistors T3 and T4.

The second active layer ACT2 may be disposed in the second semiconductor layer SCL2 and may include the second semiconductor material (e.g., the oxide semiconductor) different from the first semiconductor material. For example, the second active layer ACT2 may include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn) and oxygen (O)).

The second active layer ACT2 may include a second channel region CHA2, a second source region S2, and a second drain region D2. The second channel region CHA2 may overlap the second gate electrode G2 in the third direction DR3. The second source region S2 may be disposed on one side of the second channel region CHA2, and the second drain region D2 may be disposed on the other side of the second channel region CHA2. The second source region S2 and the second drain region D2 may be regions doped with ions or impurities to give conductivity to the second active layer ACT2. In an embodiment, the second source region S2 may be a source electrode of the second thin film transistor TFT2. In another embodiment, the second thin film transistor TFT2 may include a separate source electrode connected to the second source region S2. In an embodiment, the second drain region D2 may be a drain electrode of the second thin film transistor TFT2. In another embodiment, the second thin film transistor TFT2 may include a separate drain electrode connected to the second drain region D2.

The fourth insulating film 126 may be disposed on the second semiconductor layer SCL2. The fourth insulating film 126 may cover the second semiconductor layer SCL2.

The third conductive layer CDL3 may be disposed on the fourth insulating film 126. The third conductive layer CDL3 may include the second gate electrode G2 of the second thin film transistor TFT2. The second gate electrode G2 may be disposed in the third conductive layer CDL3 overlapping a portion (e.g., the second channel region CHA2) of the second active layer ACT2. In an embodiment, the third conductive layer CDL3 may further include at least one signal line (or a portion of the at least one signal line), a conductive pattern (e.g., a bridge pattern), and/or a capacitor electrode.

In an embodiment, the respective electrodes, conductive patterns, and/or signal lines constituting the bottom conductive layer BCDL, the first conductive layer CDL1, the second conductive layer CDL2, and the third conductive layer CLD3 may include a conductive material (e.g., at least one of molybdenum (Mo), aluminum (Al), chromium (Cr), gold (Au), titanium (Ti), nickel (Ni), neodymium (Nd), copper (Cu), and other metals, alloys thereof, or other conductive materials), and may have a single-layer or multilayer structure. For example, the respective electrodes, conductive patterns, and/or lines constituting the bottom conductive layer BCDL, the first conductive layer CDL1, the second conductive layer CDL2, and the third conductive layer CLD3 may be molybdenum (Mo) or other metal materials. At least two of the bottom conductive layer BCDL, the first conductive layer CDL1, the second conductive layer CDL2, and the third conductive layer CLD3 may include the same material or include different materials. A material of each of the bottom conductive layer BCDL, the first conductive layer CDL1, the second conductive layer CDL2, and the third conductive layer CLD3 is not limited, and may be variously changed according to embodiments.

The fifth insulating film 127 may be disposed on the third conductive layer CDL3. The fifth insulating film 127 may cover the third conductive layer CDL3.

In an embodiment, the first insulating film 123, the second insulating film 124, the third insulating film 125, the fourth insulating film 126, and the fifth insulating film 127 may be inorganic insulating films including an inorganic insulating material (e.g., silicon nitride, silicon oxide, silicon oxynitride, titanium oxide, aluminum oxide, or other inorganic insulating material), and may have a single-layer or multilayer structure. At least two of the first insulating film 123, the second insulating film 124, the third insulating film 125, the fourth insulating film 126, and the fifth insulating film 127 may include the same material or include different materials. A material of each of the first insulating film 123, the second insulating film 124, the third insulating film 125, the fourth insulating film 126, and the fifth insulating film 127 may be variously changed according to embodiments.

The fourth conductive layer CDL4 may be disposed on the fifth insulating film 127. The fourth conductive layer CDL4 may include the first connection electrode CNE1 (or the drain electrode of the first thin film transistor TFT1), a first bridge electrode BE1 (or the source electrode of the second thin film transistor TFT2), and a second bridge electrode BE2 (or the drain electrode of the second thin film transistor TFT2). The first connection electrode CNE1 may be disposed in the fourth conductive layer CDL4 and be connected to the first drain region D1 of the first active layer ACT1 through a first contact hole CH1 formed through the first insulating film 123, the second insulating film 124, the third insulating film 125, the fourth insulating film 126, and the fifth insulating film 127. The first bridge electrode BE1 may be disposed in the fourth conductive layer CDL4 and be connected to the second source region S2 of the second active layer ACT2 through a second contact hole CH2 formed through the fourth insulating film 126 and the fifth insulating film 127. The second bridge electrode BE2 may be connected to the second drain region D2 of the second active layer ACT2 through a third contact hole CH3 formed through the fourth insulating film 126 and the fifth insulating film 127. In an embodiment, the fourth conductive layer CDL4 may further include at least one signal line (or a portion of the at least one signal line) and/or a conductive pattern (e.g., a bridge pattern). As an example, the fourth conductive layer CDL4 may include portions of the power lines PL (e.g., the first pixel power line VDL and/or the second pixel power line VSL) provided inside and/or outside the display area DA.

The sixth insulating film 128 may be disposed on the fourth conductive layer CDL4. The sixth insulating film 128 may cover the fourth conductive layer CDL4.

The fifth conductive layer CDL5 may be disposed on the sixth insulating film 128. The fifth conductive layer CDL5 may include the second connection electrode CNE2. The second connection electrode CNE2 may be disposed in the fifth conductive layer CDL5 and be connected to the first connection electrode CNE1 through a fourth contact hole CH4 (or a first via hole) formed through the sixth insulating film 128. In an embodiment, the fifth conductive layer CDL5 may further include at least one signal line (or a portion of the at least one signal line) and/or a conductive pattern (e.g., a bridge pattern). As an example, the fifth conductive layer CDL5 may include portions of the power lines PL (e.g., the first pixel power line VDL and/or the second pixel power line VSL) provided inside and/or outside the display area DA.

In an embodiment, the respective electrodes, conductive patterns, and/or lines constituting the fourth conductive layer CDL4 and the fifth conductive layer CLD5 may include a conductive material (e.g., at least one of molybdenum (Mo), aluminum (Al), chromium (Cr), gold (Au), titanium (Ti), nickel (Ni), neodymium (Nd), copper (Cu), and other metals, alloys thereof, or other conductive materials), and may have a single-layer or multilayer structure. For example, the respective electrodes, conductive patterns, and/or lines constituting the fourth conductive layer CDL4 and the fifth conductive layer CDL5 may be formed in a triple-layer structure of titanium/aluminum/titanium (Ti/Al/Ti). The fourth conductive layer CDL4 and the fifth conductive layer CDL5 may include the same material or include different materials. A material of each of the fourth conductive layer CDL4 and the fifth conductive layer CDL5 may be variously changed according to embodiments.

The seventh insulating film 129 may be disposed on the fifth conductive layer CDL5. The seventh insulating film 129 may cover the fifth conductive layer CDL5.

In an embodiment, the sixth insulating film 128 and the seventh insulating film 129 may be organic insulating films including an organic insulating material (e.g., an acrylic resin, an epoxy resin, a phenolic resin, a polyamide resin, a polyimide resin, or other organic insulating materials) in order to planarize the circuit layer 120, and may have a single-layer or multilayer structure. The sixth insulating film 128 and the seventh insulating film 129 may include the same material or include different materials. A material of each of the sixth insulating film 128 and the seventh insulating film 129 may be variously changed according to embodiments.

The light emitting element layer 130 may include a pixel defining film 131 partitioning emission areas EA of the pixels PX and the respective light emitting elements EL positioned in the respective emission areas EA. In an embodiment, the light emitting element layer 130 may further include a spacer 132 disposed on a portion of the pixel defining film 131.

Each light emitting element EL may include a first electrode ET1 (e.g., an anode electrode) connected to at least one transistor T (e.g., the first thin film transistor TFT1) included in a corresponding pixel PX through the first connection electrode CNE1, the second connection electrode CNE2, and the like, and a light emitting layer EML and a second electrode ET2 (e.g., a cathode electrode) that are sequentially disposed on the first electrode ET1. In an embodiment, the light emitting element EL may further include a first intermediate layer (e.g., a hole layer including a hole transport layer) interposed between the first electrode ET1 and the light emitting layer EML and a second intermediate layer (e.g., an electron layer including an electron transport layer) interposed between the light emitting layer EML and the second electrode ET2.

The first electrode ET1 of the light emitting element EL may include a conductive material and may be disposed on the circuit layer 120. For example, the first electrode ET1 may be disposed on the seventh insulating film 129 to correspond to each emission area EA. The first electrode ET1 may be connected to the second connection electrode CNE2 through a fifth contact hole CH5 (or a second via hole) formed through the seventh insulating film 129.

In an embodiment, the first electrode ET1 may include a metal material having high reflectivity. For example, the first electrode ET1 may have a single-layer structure of molybdenum (Mo), titanium (Ti), copper (Cu), or aluminum (Al) or have a multilayer structure (e.g., ITO/Mg, ITO/MgF, ITO/Ag, ITO/Ag/ITO, etc.) including indium-tin-oxide (ITO), indium-zinc-oxide (IZO), zinc oxide (ZnO), or indium oxide (In₂O₃), and silver (Ag), magnesium (Mg), aluminum (Al), platinum (Pt), lead (Pb), gold (Au), nickel (Ni), or the like. The light emitting layer EML of the light emitting element EL may include a high molecular material or a low molecular material. Light emitted from the light emitting layer EML may contribute to image display. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by the pixels PX of different colors, and wavelength conversion layers and/or color filters corresponding to colors (or wavelength bands) of light to be emitted from the respective pixels PX may be disposed in the emission areas EA of at least some of the pixels PX.

The second electrode ET2 of the light emitting element EL may include a conductive material and may be connected to the second pixel power line VSL. In an embodiment, the second electrode ET2 may be a common film formed over the entire display area DA in a form in which it covers the light emitting layers EML and the pixel defining film 131. In an embodiment, the second electrode ET2 may be made of a transparent conductive material (TCO) such as ITO or IZO capable of transmitting light therethrough or a semi-transmissive conductive material such as magnesium (Mg), silver (Ag), or an alloy of magnesium (Mg) and silver (Ag). When the second electrode ET2 is made of the semi-transmissive conductive material, an improvement in light emission efficiency due to a micro cavity effect may be expected.

The pixel defining film 131 may have openings corresponding to the respective emission areas EA and surround the emission areas EA. For example, the pixel defining film 131 may be formed to cover an edge of the first electrode ET1 of the light emitting element EL, and may include an opening exposing the other portion of the first electrode ET1. An area in which the exposed first electrode ET1 and the light emitting layer EML overlap each other (or an area including such an area) may be defined as the emission area EA of each pixel PX.

In an embodiment, the pixel defining film 131 may include at least one organic film including an organic insulating material. For example, the pixel defining film 131 may include a polyacrylates resin, an epoxy resin, a phenolic resin, a polyamides resin, a polyimides resin, an unsaturated polyesters resin, a polyphenyleneethers resin, a polyphenylenesulfides resin, benzocyclobutene (BCB), or other organic insulating materials.

The spacer 132 may be disposed on a portion of the pixel defining film 131. The spacer 132 may include at least one organic film including an organic insulating material. The spacer 132 may include the same material as the pixel defining film 131 or include a different material from the pixel defining film 131. In an embodiment, the pixel defining film 131 and the spacer 132 may be sequentially formed through respective mask processes. In another embodiment, the pixel defining film 131 and the spacer 132 may be simultaneously formed using a halftone mask. In this case, the pixel defining layer 131 and the spacer 132 may be regarded as a single insulating film integral with each other. The organic insulating material constituting the spacer 132 is not particularly limited, and may be variously changed according to embodiments.

The encapsulation layer 140 may be disposed on the light emitting element layer 130 in the main area MA. For example, the encapsulation layer 140 may be disposed in the display area DA and the non-display area NA so as to cover the light emitting element layer 130. The encapsulation layer 140 may block penetration of oxygen or moisture into the light emitting element layer 130 and alleviate an electrical or physical impact on the circuit layer 120 and the light emitting element layer 130.

In an embodiment, the encapsulation layer 140 may include a first inorganic encapsulation film 141, an organic encapsulation film 142, and a second inorganic encapsulation film 143 that are sequentially disposed on the light emitting element layer 130. The first inorganic encapsulation film 141 and the second inorganic encapsulation film 143 may include an inorganic material, and the organic encapsulation film 142 may include an organic material.

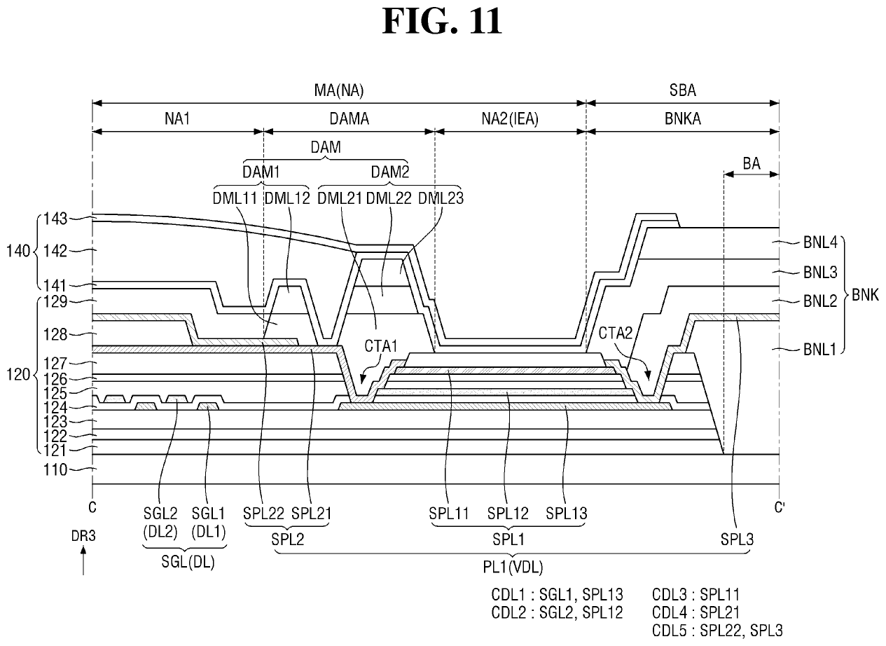

In an embodiment, the organic encapsulation film 142 may be provided by dropping an organic material in a liquid phase onto the first inorganic encapsulation film 141, diffusing the organic material so as to cover the display area DA, and curing the organic material. In addition, the display panel 100 may include at least one dam (e.g., a dam DAM of FIG. 11) in order to prevent the organic material of the organic encapsulation film 142 from overflowing. The dam may be disposed in the non-display area NA disposed adjacent to the display area DA to surround the display area DA. For example, the dam may be disposed in the dam area DAMA of the non-display area NA.

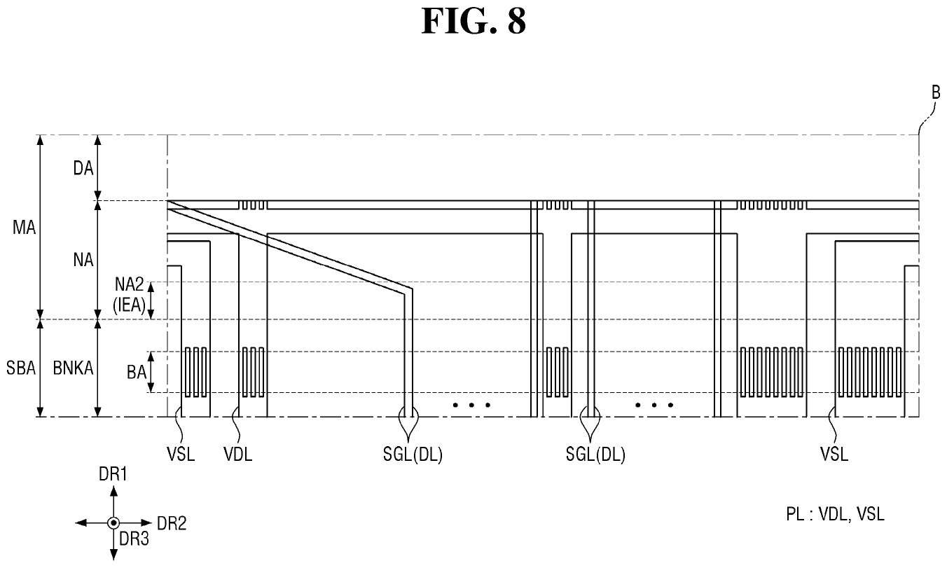

FIG. 8 is a plan view illustrating area B of FIG. 4. For example, FIG. 8 illustrates an embodiment of power lines PL and signal lines SGL disposed in area B of FIG. 4. In FIG. 8, a first pixel power line VDL and a second pixel power line VSL are illustrated as an example of the power lines PL that may be provided in the display panel 100, and data lines DL (or data connection lines) are illustrated as an example of the signal lines SGL that may be provided in the display panel 100.

Referring to FIG. 8, the display device 10 may include the power lines PL and the signal lines SGL provided in the display panel 100 and extending from the sub-area SBA to the main area MA. Only the power lines PL and the signal lines SGL positioned in the non-display area NA of the main area MA and the sub-area SBA have been illustrated in FIG. 8, but the power lines PL (or some of the power lines PL) and the signal lines SGL (or some of the signal lines SGL) may also extend to an inner portion of the display area DA to be connected to the pixels PX. For example, the power lines PL and the signal lines SGL positioned in the non-display area NA and the sub-area SBA may be connected to respective horizontal and/or vertical power lines and signal lines SGL formed inside the display area DA inside the display area DA or around the display area DA.

The power lines PL may include at least one first pixel power line VDL and at least one second pixel power line VSL. Depending on a structure of the pixels PX, the display panel 100 may further include at least one power line supplying an additional source voltage.

The first pixel power line VDL and the second pixel power line VSL may extend from the respective power pads provided in the pad area PA of the sub-area SBA to the display area DA through the bank area BNKA including the bending area BA, the second non-display area NA2 including the inorganic encapsulation area IEA, and the like. In an embodiment, the second pixel power line VSL may be connected to the second electrodes

ET2 of the light emitting elements EL outside the display area DA. The first pixel power line VDL and the second pixel power line VSL may be connected to the pixels PX positioned in the display area DA to supply the first pixel power voltage ELVDD and the second pixel power voltage ELVSS to the pixels PX, respectively.

In an embodiment, the power lines PL may have a greater width and/or area than the signal lines SGL. For example, each of the first pixel power line VDL and the second pixel power line VSL may have a greater width and a grater area than the signal lines SGL in at least the second direction DR2. Accordingly, a drop of the source voltage may be reduced or minimized, and the pixels PX may be stably driven.

In an embodiment, the power lines PL in the bending area BA and/or around the bending area BA may include a plurality of lines having a width narrower than those in the sub-area SBA other than the bending area BA, the non-display area NA, and the like. For example, each of the first pixel power line VDL and the second pixel power line VSL may include at least one opening in the bending area BA and/or around the bending area BA. Accordingly, flexibility of the power lines PL may be increased.

In addition, types, structures, shapes, the number, positions, and the like, of the power lines PL may be variously changed according to embodiments.

The signal lines SGL may supply respective driving signals to the pixels PX. For example, the signal lines SGL may include data lines DL supplying respective data signals to the pixels PX. The data lines DL may extend from pads connected to the driving circuit 200 (e.g., output pads of the driving circuit 200 provided in the driving circuit mounting area ICA) to the display area DA through the bank area BNKA including the bending area BA, the second non-display area NA2 including the inorganic encapsulation area IEA, and the like. The data lines DL may be connected to the pixels PX arranged in respective pixel columns of the display area DA to supply the respective data signals to the pixels PX.

In an embodiment, some of the data lines DL may extend from the driving circuit mounting area ICA to the display area DA along the first direction DR1 and may be directly connected to the pixels PX. The others (also referred to as “data connection lines”) of the data lines DL may extend from the driving circuit mounting area ICA to the display area DA along the first direction DR1, and may be connected to the respective data lines DL provided in the respective pixel columns through respective horizontal connection lines extending in the second direction DR2 inside the display area DA.

In an embodiment, when the display panel 100 includes the embedded circuit and the like disposed in the main area MA, the power lines PL may further include lines supplying driving voltages to the embedded circuit, and the signal lines SGL may further include lines supplying driving signals to the embedded circuit. In an embodiment, when the display panel 100 does not include the embedded circuit and scan signals are supplied from the driving circuit 200 to the display panel 100, the signal lines SGL may further include scan lines SL connected between the driving circuit 300 and the pixels PX (or scan connection lines for connecting scan lines SL inside the display area DA to the driving circuit 200).

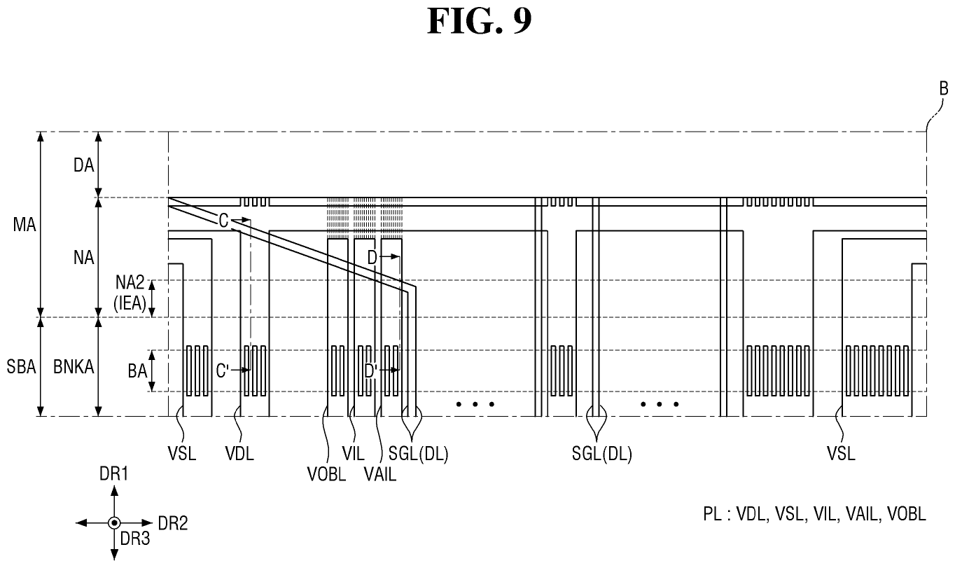

FIG. 9 is a plan view illustrating area B of FIG. 4. For example, FIG. 9 illustrates a modified embodiment of an embodiment of FIG. 8.

Referring to FIG. 9, the power lines PL may further include at least one of a first initialization power line VIL, a second initialization power line VAIL, and a bias power line VOBL in addition to the first pixel power line VDL and the second pixel power line VSL. For example, in the display device 10 including the pixel PX illustrated in FIG. 6, the power lines PL may further include the first initialization power line VIL, the second initialization power line VAIL, and the bias power line VOBL. Types, the number, and the like, of power lines PL may be changed depending on a structure of the pixels PX.

The first initialization power line VIL, the second initialization power line VAIL, and the bias power line VOBL may extend from the respective power pads provided in the pad area PA of the sub-area SBA to the display area DA through the bank area BNKA including the bending area BA, the second non-display area NA2 including the inorganic encapsulation area IEA, and the like. The first initialization power line VIL, the second initialization power line VAIL, and the bias power line VOBL may be connected to the pixels PX positioned in the display area DA to supply the first initialization voltage VINT, the second initialization voltage VAINT, and the bias voltage VOBS to the pixels PX, respectively.

In an embodiment, each of the first initialization power line VIL, the second initialization power line VAIL, and the bias power line VOBL may be formed to have a greater width and/or area than the signal lines SGL. Accordingly, a drop of the source voltage may be reduced or minimized.

In an embodiment, the first initialization power line VIL, the second initialization power line VAIL, and the bias power line VOBL in the bending area and/or around the bending area BA may include a plurality of lines having a width narrower than those in the sub-area SBA other than the bending area BA, the non-display area NA, and the like. For example, each of the first initialization power line VIL, the second initialization power line VAIL, and the bias power line VOBL may include at least one opening in the bending area BA and/or around the bending area BA. Accordingly, flexibility of the first initialization power line VIL, the second initialization power line VAIL, and the bias power line VOBL may be increased.

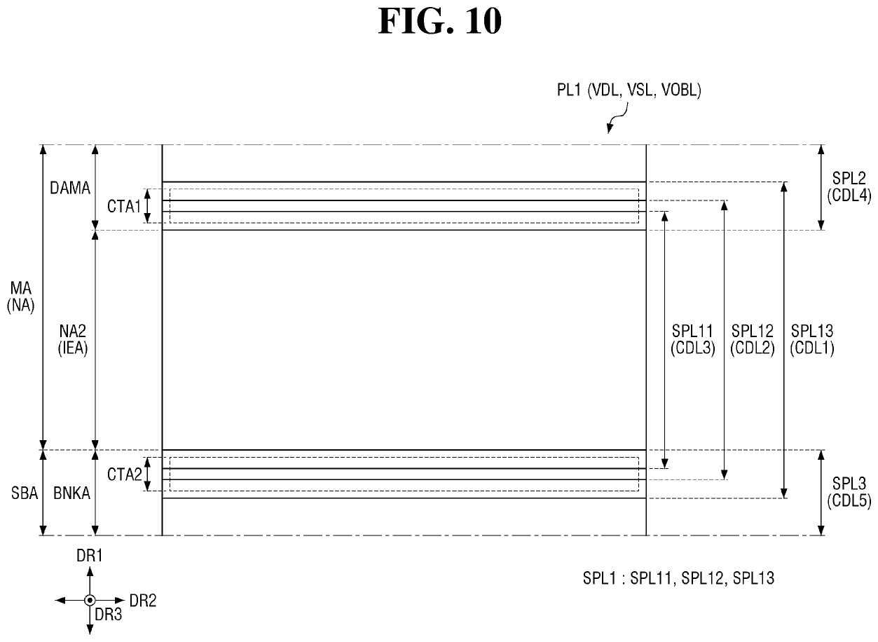

FIG. 10 is a plan view illustrating a first power line PL1 according to an embodiment. For example, FIG. 10 illustrates a portion of the first power line PL1 passing through the second non-display area NA2. In an embodiment, the first power line PL1 may be one of the first pixel power line VDL, the second pixel power line VSL, and the bias power line VOBL. The first pixel power line VDL, the second pixel power line VSL, and the bias power line VOBL may be disposed in the same layer in the second non-display area NA2 and around the second non-display area NA2, and may have substantially the same or similar cross-sectional structure.

FIG. 11 is a cross-sectional view illustrating an embodiment of a cross section taken along line C-C′ of FIG. 9. For example, FIG. 11 illustrates a cross-sectional structure of the first pixel power line VDL as a representative of the first power line PL1.

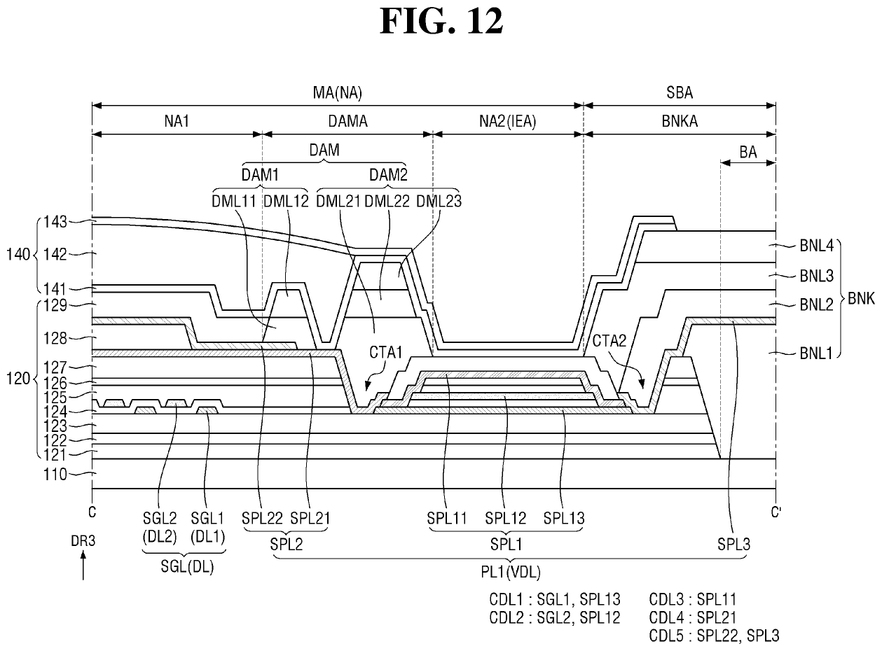

FIG. 12 is a cross-sectional view illustrating an embodiment of a cross section taken along line C-C′ of FIG. 9. For example, FIG. 12 illustrates a cross-sectional structure according to an embodiment different from an embodiment of FIG. 11 in a first contact part CTA1 and a second contact part CTA2.

Referring to FIGS. 10 to 12, the first power line PL1 (also referred to as a “first line”) may include a first sub-line SPL1 positioned in the second non-display area NA2 which is a inorganic encapsulation area IEA, a dam area DAMA disposed adjacent to the second non-display area NA2, and the bank area BNKA disposed adjacent to the second non-display area NA2, a second sub-line SPL2 connected to one end of the first sub-line SPL1 and positioned in the dam area DAMA and the first non-display area NA1, and a third sub-line SPL3 connected to the other end of the first sub-line SPL1 and positioned in the bank area BNKA. The first sub-line SPL1 may be connected to the second sub-line SPL2 and the third sub-line SPL3 inside the second non-display area NA2 or in the dam area DAMA disposed adjacent to the second non-display area NA2 and the bank area BNKA disposed adjacent to the second non-display area NA2, respectively.

For example, the first sub-line SPL1 may extend from the dam area DAMA to the bank area BNKA through the second non-display area NA2, and may be connected to the second sub-line SPL2 at the first contact part CTA1 provided in the dam area DAMA and the third sub-line SPL3 at the second contact part CTA2 provided in the bank area BNKA, respectively. Each of the first contact part CTA1 and the second contact part CTA2 may include at least one contact hole or via hole formed through a single etching process or etching processes performed at least twice.

In the second non-display area NA2, the first power line PL1 may be disposed below at least one inorganic insulating film provided in the circuit layer 120, and may be covered by the at least one inorganic insulating film. For example, in the second non-display area NA2, the first power line PL1 may be disposed in at least the third conductive layer CDL3, and may be covered by the fifth insulating film 127 including an inorganic insulating material.

As an example, the first sub-line SPL1 may include a first line layer SPL11 disposed in the third conductive layer CDL3 and covered by the fifth insulating film 127 in the second non-display area NA2. The first sub-line SPL1 may be formed as a single-layer or multilayer line in the second non-display area NA2.

In an embodiment, the first sub-line SPL1 may further include a second line layer SPL12 disposed in the second conductive layer CDL2 and a third line layer SPL13 disposed in the first conductive layer CDL1, and accordingly, may be formed as a multilayer line. For example, the first sub-line SPL1 may be formed as a multilayer line further including at least one of a second line layer SPL12 disposed in the second conductive layer CDL2 and a third line layer SPL13 disposed in the first conductive layer CDL1 in addition to the first line layer SPL11. As an example, the first sub-line SPL1 may be formed as a triple-layer line including the first line layer SPL11, the second line layer SPL12, and the third line layer SPL13 in the second non-display area NA2. Accordingly, resistance of the first power line PL1 including the first sub-line SPL1 may be reduced.

In an embodiment, the line layers SPL11, SPL12, and SPL13 of the first sub-line SPL1 may be electrically connected to each other through the second sub-line SPL2 and/or the third sub-line SPL3. For example, as illustrated in FIG. 11, one ends of the first line layer SPL11, the second line layer SPL12, and the third line layer SPL13 of the first sub-line SPL1 may be electrically connected to the second sub-line SPL2 at the first contact part CTA1 disposed in the dam area DAMA, and the other ends of the first line layer SPL11, the second line layer SPL12, and the third line layer SPL13 of the first sub-line SPL1 may be electrically connected to the third sub-line SPL3 at the second contact part CTA2 disposed in the bank area BNKA.

In another embodiment, the line layers SPL11, SPL12, and SPL13 of the first sub-line SPL1 may be directly connected to each other. For example, the first line layer SPL11 of the first sub-line SPL1 may be in direct contact with at least one of the second line layer SPL12 and the third line layer SPL13. As an example, as illustrated in FIG. 12, the first line layer SPL11 of the first sub-line SPL1 and the second line layer SPL12 of the first sub-line SPL1 may be in direct contact with the third line layer SPL13 at both ends thereof. In addition, at least one of the first line layer SPL11, the second line layer SPL12, and the third line layer SPL13 of the first sub-line SPL1 may be in contact with the second sub-line SPL2 at the first contact part CTA1 and with the third sub-line SPL3 at the second contact part CTA2, respectively. For example, the first line layer SPL11 and the third line layer SPL13 of the first sub-line SPL1 may be in direct contact with the second sub-line SPL2 at the first contact part CTA1 and with the third sub-line SPL3 at the second contact part CTA2, respectively.

A connection structure of the first sub-line SPL1, the second sub-line SPL2, and the third sub-line SPL3 is not limited to those of the above-described embodiments. For example, a connection structure of the first sub-line SPL1, the second sub-line SPL2, and the third sub-line SPL3 may be variously changed according to embodiments.

The second non-display area NA2 is an area including the inorganic encapsulation area IEA which is disposed outside the dam area DAMA, and, for example, a portion of the second non-display area NA2 or the entirety of the second non-display area NA2 may be the inorganic encapsulation area IEA. The inorganic encapsulation area IEA is an area in which the inorganic encapsulation films (e.g., the first inorganic encapsulation film 141 and the second inorganic encapsulation film 143) of the encapsulation layer 140 are directly contacting each other, and may be an area that does not include an organic insulating film. For example, the organic insulating films (e.g., the sixth insulating film 128 and the seventh insulating film 129) of the circuit layer 120 may be removed in the inorganic encapsulation area IEA. In addition, the organic encapsulation film 142 of the encapsulation layer 140 may be prevented from overflowing to the inorganic encapsulation area IEA by at least one dam DAM provided in the dam area DAMA, and thus, the organic encapsulation film 142 may not be provided in the inorganic encapsulation area IEA.

For example, the encapsulation layer 140 may be provided in at least the display area DA to cover the light emitting element layer 130 as illustrated in FIG. 7, and may extend to the non-display area NA around the display area DA as illustrated in FIGS. 11 and 12. The encapsulation layer 140 may include the inorganic encapsulation films, for example, the first inorganic encapsulation film 141 and the second inorganic encapsulation film 143, disposed to overlap each other in the display area DA to cover the light emitting element layer 130 and directly contacting each other in the inorganic encapsulation area IEA, and the organic encapsulation film 142 interposed between the first inorganic encapsulation film 141 and the second inorganic encapsulation film 143 in the display area DA may be prevented from overflowing over at least one dam DAM. For example, the organic encapsulation film 142 may be blocked by the second dam DAM2 in the dam area DAMA, and the first inorganic encapsulation film 141 and the second inorganic encapsulation film 143 may be directly contacting each other on the second dam DAM2 and the second non-display area NA2 immediately adjacent to the second dam DAM2 in the dam area DAMA.

The dam DAM may be provided in the dam area DAMA between the display area DA and the inorganic encapsulation area IEA, and may be disposed on the first power line PL1. For example, the dam DAM may cover the first contact part CTA1.

The dam DAM may include at least one of the first dam DAM1 and the second dam DAM2. Each of the first dam DAM1 and the second dam DAM2 may include at least one organic film.

In an embodiment, the first dam DAM1 may include a first dam layer DML11 and a second dam layer DML12 disposed on the first dam layer DML11. The first dam DAM1 may be formed simultaneously with at least one organic film positioned in the display area DA using the same material as the at least one organic film. For example, the first dam layer DML11 may include the same material as the sixth insulating film 128 and/or the seventh insulating film 129, and may be formed at substantially the same layer as the sixth insulating film 128 and/or the seventh insulating film 129. In this case, the first dam layer DML11 may be portions of the sixth insulating film 128 and/or the seventh insulating film 129. The second dam layer DML12 may include the same material as the pixel defining film 131 and/or the spacer 132, and may be formed at substantially the same layer as the pixel defining film 131 and/or the spacer 132. In this case, the second dam layer DML12 may be portions of the pixel defining film 131 and/or the spacer 132.

In an embodiment, the second dam DAM2 may include a first dam layer DML21, a second dam layer DML22 disposed on the first dam layer DML21, and a third dam layer DML23 disposed on the second dam layer DML22. The second dam DAM2 may be formed simultaneously with at least one organic film positioned in the display area DA using the same material as the at least one organic film. For example, the first dam layer DML21 may include the same material as the sixth insulating film 128, and may be formed of substantially the same layer as the sixth insulating film 128. In this case, the first dam layer DML21 may be a portion of the sixth insulating film 128. The second dam layer DML22 may include the same material as the seventh insulating film 129, and may be formed at substantially the same layer as the seventh insulating film 129. In this case, the second dam layer DML22 may be a portion of the seventh insulating film 129. The third dam layer DML23 may include the same material as the pixel defining film 131 and/or the spacer 132, and may be formed at substantially the same layer as the pixel defining film 131 and/or the spacer 132. In this case, the third dam layer DML23 may be portions of the pixel defining film 131 and/or the spacer 132.

Since at least one dam DAM is spaced apart from the display area DA, a valley may be formed between the dam area DAMA and the display area DA and/or between adjacent dams DAM. An area to which the organic encapsulation film 142 is formed may be limited by the dam DAM. The first inorganic encapsulation film 141 and the second inorganic encapsulation film 143 may be formed only up to a portion of a bank BNK disposed adjacent to the dam DM (for example, a portion between the display area DA and the bending area BA). For example, edge portions of the first inorganic encapsulation film 141 and the second inorganic encapsulation film 143 may be disposed on an upper portion of the bank BNK. In the inorganic encapsulation area IEA, by forming the first sub-line SPL1 using

at least one conductive lines disposed below the third conductive layer CDL3 which is covered by at least one fifth insulating film 127, damage to the first power line PL1 may be prevented. For example, by protecting the first power line PL1 by the fifth insulating film 127 or the like, damage to the first power line PL1 during subsequent processes may be prevented. In addition, encapsulation performance of the display device 10 may be improved by blocking a path through which moisture permeation may occur in the inorganic encapsulation area IEA. Accordingly, a length of the inorganic encapsulation area IEA may be shortened, and the non-display area NA may be reduced.

The first power line PL1 may be disposed in at least one of the fourth conductive layer CDL4 and the fifth conductive layer CDL5 in at least portions of the first non-display area NA1 and the dam area DAMA, and may be formed as a single-layer or multilayer line. For example, the second sub-line SPL2 may include at least one of a first line layer SPL21 disposed in the fourth conductive layer CDL4 and a second line layer SPL22 disposed the fifth conductive layer CDL5. As an example, the second sub-line SPL2 may be formed as a double-layer line including the first line layer SPL21 and the second line layer SPL22 in at least portions of the first non-display area NA1 and the dam area DAMA. Structures of the conductive layer of the first power line PL1 in at least portions of the first non-display area NA1 and the dam area DAMA are not limited thereto, and may be variously changed according to embodiments.

The first power line PL1 may extend to the display area DA to be connected to the pixels PX. The first power line PL1 may include at least one of the fourth conductive layer CDL4 and the fifth conductive layer CDL5 in the display area DA, but embodiments are not limited thereto.

The first power line PL1 disposed in at least a portion of the bank area BNKA may include the fifth conductive layer CDL5. For example, the third sub-line SPL3 may be formed as a single-layer line disposed in the fifth conductive layer CDL5 at least in the bending area BA.

The bank area BNKA is an area positioned outside the inorganic encapsulation area IEA, and may include the bending area BA and an area disposed around the bending area BA. The bank BNK including at least one organic film may be provided in the bank area BNKA.

In the bending area BA, inorganic films (e.g., the barrier film 121, the buffer film 122, the first, second, third, fourth, and fifth insulating films 123, 124, 125, 126, and 127 of the circuit layer 120) may be removed. Accordingly, the occurrence of cracks in the inorganic films relatively vulnerable to bending stress may be prevented. The bank BNK may cover openings formed in the inorganic layers in the bending area BA, and protect the power lines PL and the signal lines SGL passing through the bending area BA. For example, the bank BNK may include at least one organic film disposed on the power lines PL and the signal lines SGL in the bank area BNKA.

In an embodiment, the bank BNK may include a first bank layer BNL1, a second bank layer BNL2 disposed on the first bank layer BNL1, a third bank layer BNL3 disposed on the second bank layer BNL2, and a fourth bank layer BNL4 disposed on the third bank layer BNL3. A structure of the bank BNK may be variously changed according to embodiments. For example, the bank BNK may not include at least one of the first bank layer BNL1, the second bank layer BNL2, the third bank layer BNL3, and the fourth bank layer BNL, or at least two of the first bank layer BNL1, the second bank layer BNL2, the third bank layer BNL3, and the fourth bank layer BNL4 may be integrated as one bank layer.

In an embodiment, the bank BNK may be formed simultaneously with at least one organic film positioned in the display area DA using the same material as the at least one organic film. For example, the first bank layer BNL1 may include the same material as the sixth insulating film 128, and may be formed of substantially the same layer as the sixth insulating film 128. The first bank layer BNL1 may be a portion of the sixth insulating film 128. The second bank layer BNL2 may include the same material as the seventh insulating film 129, and may be formed of substantially the same layer as the seventh insulating film 129. The second bank layer BNL2 may be a portion of the seventh insulating film 129. The third bank layer BNL3 may include the same material as the pixel defining film 131, and may be formed of substantially the same layer as the pixel defining film 131. The third bank layer BNL3 may be a portion of the pixel defining film 131. The fourth bank layer BNL4 may include the same material as the spacer 132, and may be formed at substantially the same layer as the spacer 132. The fourth bank layer BNL4 may be a portion of the spacer 132.

A stacked structure and a material of the bank BNK are not limited to those of the above-described embodiment. For example, a stacked structure and a material of the bank BNK may be variously changed according to embodiments.

The signal lines SGL (also referred to as “third lines”) may be disposed in the first conductive layer CDL1 and the second conductive layer CDL2 in the non-display area NA including the first non-display area NA1. For example, the signal lines SGL may include first signal lines SGL1 (e.g., first data lines DL1 disposed in the first conductive layer CDL1) and second signal lines SGL2 (e.g., second data lines DL2 disposed in the second conductive layer CDL2) alternately disposed in the first conductive layer CDL1 and the second conductive layer CDL2 in the non-display area NA. By disposing the signal lines SGL separately at the first conductive layer CDL1 and the second conductive layer CDL2, it is possible to stably separate the signal lines SGL from each other while densely disposing the signal lines SGL.

In an embodiment, the signal lines SGL may be disposed in the fifth conductive layer CDL5 in at least a portion of the bank area BNKA. For example, the signal lines SGL may be formed as single-layer lines disposed in the fifth conductive layer CDL5 at least in the bending area BA, and may be covered by the bank BNK.

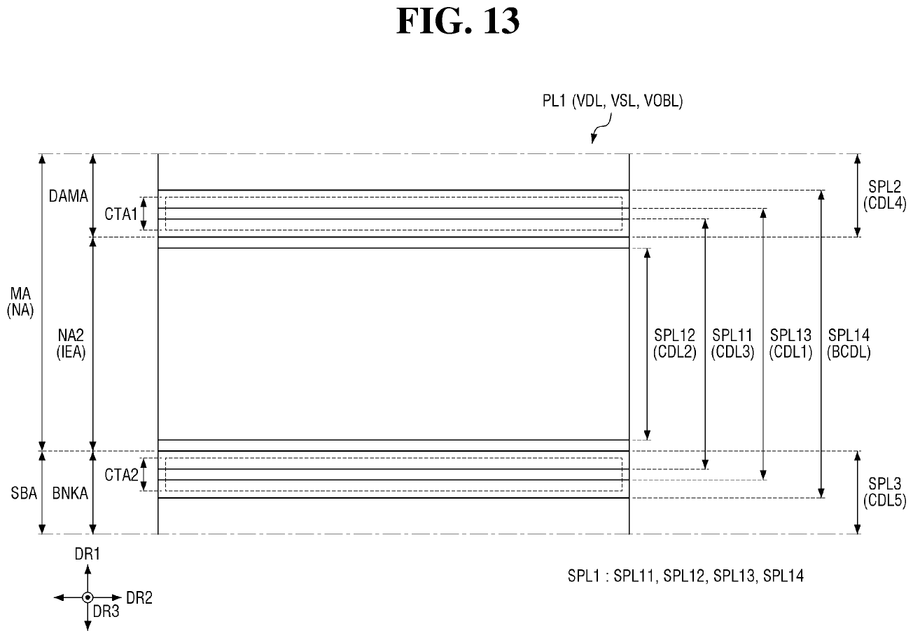

FIG. 13 is a plan view illustrating a first power line PL1 according to an embodiment. For example, FIG. 13 illustrates a portion of the first power line PL1 passing through the second non-display area NA2, and illustrates a modified embodiment of embodiments of FIGS. 10 to 12.

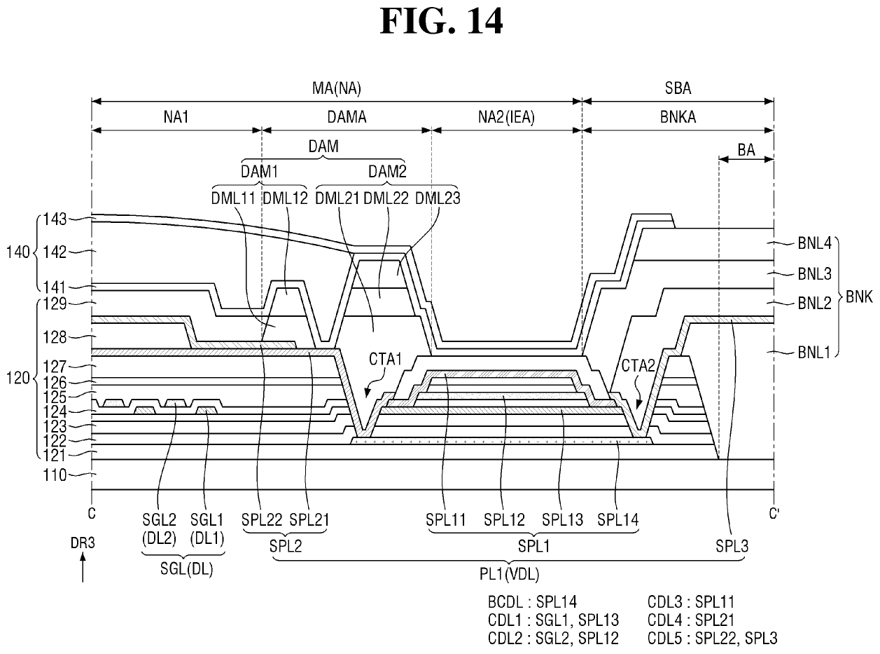

FIG. 14 is a cross-sectional view illustrating an embodiment of a cross section taken along line C-C′ of FIG. 9. For example, FIG. 14 illustrates a cross-sectional structure according to an embodiment different from embodiments of FIGS. 10 to 12 in a structure of the first sub-line SPL1.

Referring to FIGS. 13 and 14, in the inorganic encapsulation area IEA, the first power line PL1 may be formed as a multilayer line further including a fourth line layer SPL4 disposed in the bottom conductive layer BCDL. For example, in the inorganic encapsulation area IEA, the first sub-line SPL1 may be formed as a quadruple-layer line including the first line layer SPL11, the second line layer SPL12, the third line layer SPL13, and the fourth line layer SPL14. Accordingly, resistance of the first power line PL1 including the first sub-line SPL1 may be further reduced.

In an embodiment, the fourth line layer SPL14 may be electrically connected to the first line layer SPL11, the second line layer SPL12, and/or the third line layer SPL13 through the second sub-line SPL2 and the third sub-line SPL3. For example, the first line layer SPL11 may be in direct contact with the second line layer SPL12 and the third line layer SPL13 to be electrically connected to the second line layer SPL12 and the third line layer SPL13, and may be electrically connected to the fourth line layer SPL14 through the second sub-line SPL2 and the third sub-line SPL3.

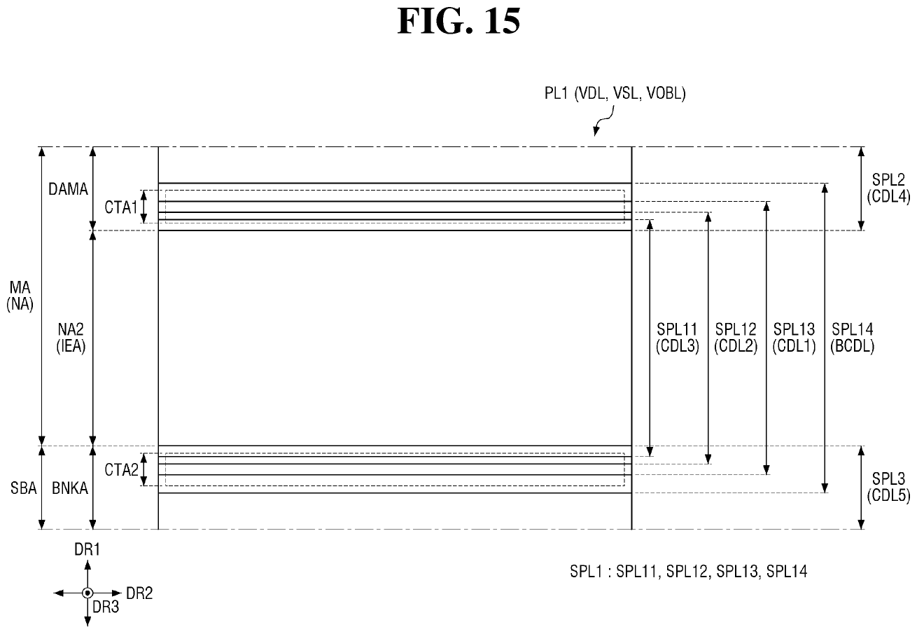

FIG. 15 is a plan view illustrating a first power line PL1 according to an embodiment. For example, FIG. 15 illustrates a portion of the first power line PL1 passing through the second non-display area NA2, and illustrates a modified embodiment of an embodiment of FIGS. 13 and 14.

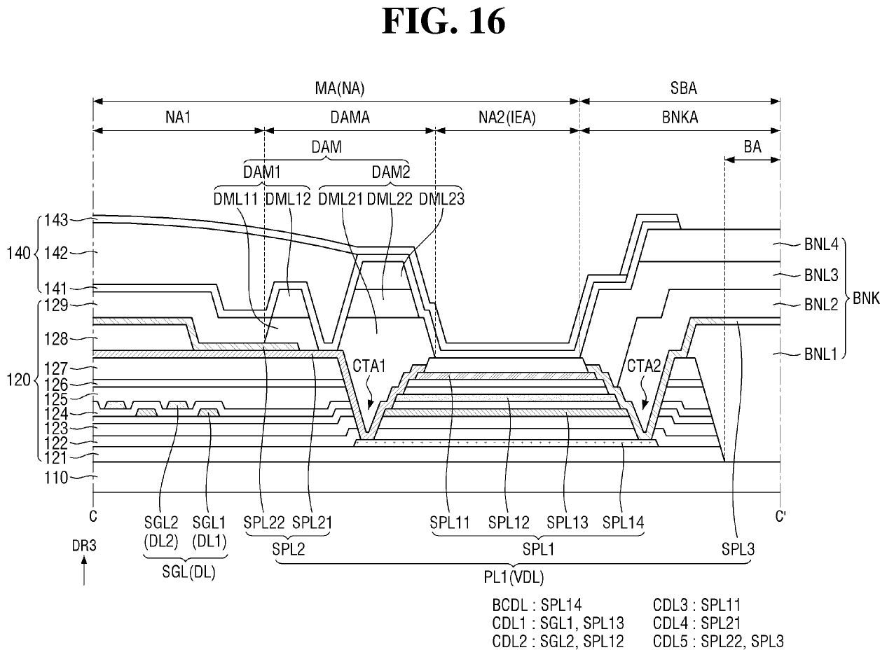

FIG. 16 is a cross-sectional view illustrating an embodiment of a cross section taken along line C-C′ of FIG. 9. For example, FIG. 16 illustrates a cross-sectional structure according to an embodiment different from an embodiment of FIGS. 13 and 14 in the first contact part CTA1 and the second contact part CTA2.

Referring to FIGS. 15 and 16, the first line layer SPL11, the second line layer SPL12, the third line layer SPL13, and the fourth line layer SPL14 of the first sub-line SPL1 may be electrically connected to each other through the second sub-line SPL2 and the third sub-line SPL3. For example, the first line layer SPL11, the second line layer SPL12, the third line layer SPL13, and the fourth line layer SPL14 of the first sub-line SPL1 may not be in direct contact with each other, and may be electrically connected to each other through the second sub-line SPL2 and the third sub-line SPL3 at the first contact part CTA1 and the second contact part CTA2, respectively.

In an embodiment, the first contact part CTA1 and the second contact part CTA2 include at least one contact hole or via hole formed through a plurality of inorganic insulating films provided in the circuit layer 120, and may include at least one contact hole or via hole formed through at least two etching processes. For example, the first contact part CTA1 and the second contact part CTA2 may be formed through at least two etching processes among processed for forming the first contact hole CH1, the second contact hole CH2, and the third contact hole CH3.

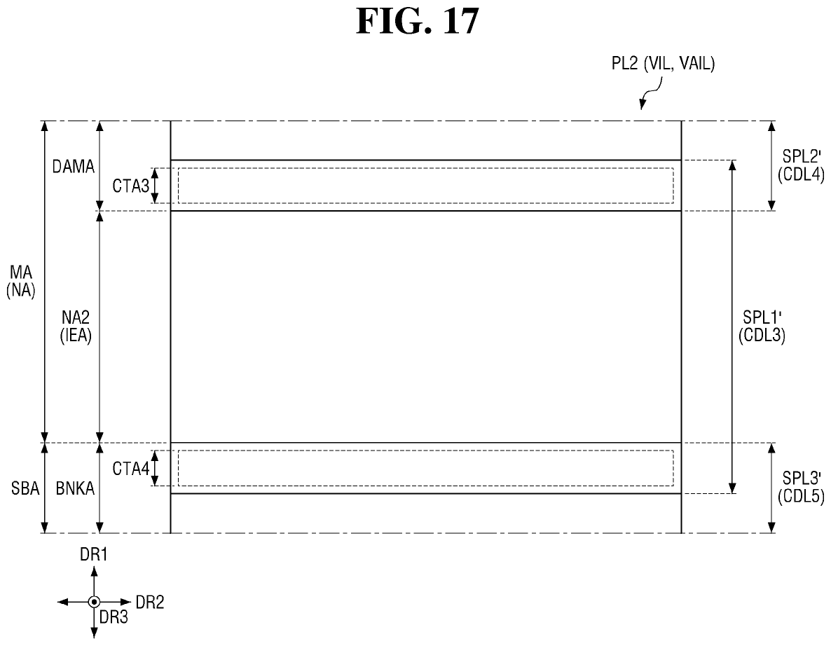

FIG. 17 is a plan view illustrating a second power line PL2 according to an embodiment. For example, FIG. 17 illustrates a portion of the second power line PL2 passing through the second non-display area NA2. In an embodiment, the second power line PL2 is a power line supplying an initialization voltage (e.g., the first initialization voltage VINT or the second initialization voltage VAINT) to the pixels PX, and may be one of the first initialization power line VIL and the second initialization power line VAIL. The first initialization power line VIL and the second initialization power line VAIL may be disposed in the same layer in the second non-display area NA2 and around the second non-display area NA2, and may have substantially the same or similar cross-sectional structure.

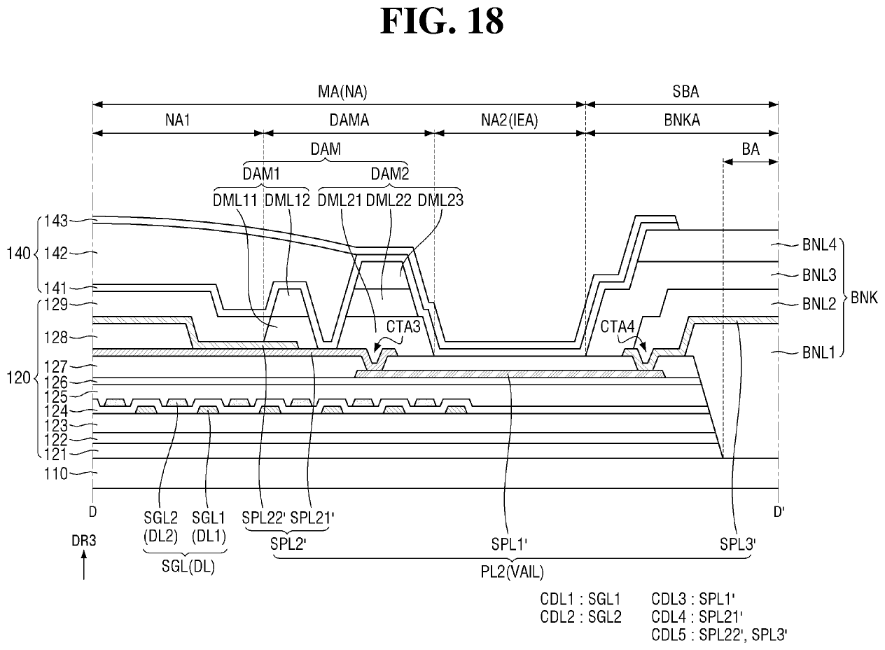

FIG. 18 is a cross-sectional view illustrating an embodiment of a cross section taken along line D-D′ of FIG. 9. For example, FIG. 18 illustrates a cross-sectional structure of the second initialization power line VAIL as a representative of the second power line PL2.

Referring to FIGS. 17 and 18, the circuit layer 120 may further include the second power line PL2 (also referred to as a “second line”) extending from the sub-area SBA to the display area DA through the second non-display area NA2 including the inorganic encapsulation area IEA and spaced apart from the first power line PL1.

The second power line PL2 may include a first sub-line SPL1′ positioned in the second non-display area NA2, a portion of the dam area DAMA, and a portion of the bank area BNKA, a second sub-line SPL2′ connected to the first sub-line SPL1′ and positioned in the dam area DAMA and the first non-display area NA1, and a third sub-line SPL3′ connected to the first sub-line SPL1′ and positioned in the bank area BNKA. The first sub-line SPL1′ may be connected to the second sub-line SPL2′ and the third sub-line SPL3′ inside the second non-display area NA2 or in the dam area DAMA and the bank area BNKA, respectively.

For example, the first sub-line SPL1′ may extend to the dam area DAMA and the bank area BNKA, and may be electrically connected to the second sub-line SPL2′ and the third sub-line SPL3′ at a third contact part CTA3 provided in the dam area DAMA and a fourth contact part CTA4 provided in the bank area BNKA, respectively. Each of the third contact part CTA3 and the fourth contact part CTA4 may include at least one contact hole or via hole.

The second power line PL2 may be disposed below at least one inorganic insulating film provided in the circuit layer 120 in the second non-display area NA2, and may be covered by the at least one inorganic insulating film. For example, the second power line PL2 may be disposed in the third conductive layer CDL3 in the second non-display area NA2, and may be covered by the fifth insulating film 127 including an inorganic insulating material.

In the inorganic encapsulation area IEA, by forming the second power line PL2 at the third conductive layer CDL3 that may be covered by the fifth insulating film 127, damage to the second power line PL2 may be prevented. For example, by protecting the second power line PL2 by the fifth insulating film 127, damage to the second power line PL2 during subsequent processes may be prevented. In addition, encapsulation performance of the display device 10 may be improved by blocking a path through which moisture permeation may occur in the inorganic encapsulation area IEA. Accordingly, a length of the inorganic encapsulation area IEA may be shortened, and the non-display area NA may be reduced.

In an embodiment, the second power line PL2 may be formed as a single-layer line in the second non-display area NA2. For example, the first sub-line SPL1′ may be formed as a single-layer line disposed in the third conductive layer CDL3 and covered by the fifth insulating film 127 in the second non-display area NA2. Accordingly, a space for forming the signal lines SGL may be sufficiently secured. For example, the second power line PL2 may be disposed in a different conductive layer from the signal lines SGL in the inorganic encapsulation area IEA and/or around the inorganic encapsulation area IEA, and may thus overlap at least one signal line SGL.

The second power line PL2 may be disposed in at least one of the fourth conductive layer CDL4 and the fifth conductive layer CDL5 in at least portions of the first non-display area NA1 and the dam area DAMA, and may be formed as a single-layer or multilayer line. For example, the second sub-line SPL2′ may include at least one of a first line layer SPL21′ disposed in the fourth conductive layer CDL4 and a second line layer SPL22′ disposed in the fifth conductive layer CDL5. As an example, the second sub-line SPL2′ may be formed as a double-layer line including the first line layer SPL21′ and the second line layer SPL22′ in at least portions of the first non-display area NA1 and the dam area DAMA. Structures of the conductive layer at which the second power line PL2 is provided and the second power line PL2 in at least portions of the first non-display area NA1 and the dam area DAMA are not limited thereto, and may be variously changed according to embodiments.

The second power line PL2 may extend to the display area DA to be connected to the pixels PX. The second power line PL2 may be disposed in at least one of the fourth conductive layer CDL4 and the fifth conductive layer CDL5 in the display area DA, but embodiments are not limited thereto.

The second power line PL2 may be disposed in the fifth conductive layer CDL5 in at least a portion of the bank area BNKA. For example, the third sub-line SPL3′ may be formed as a single-layer line disposed in the fifth conductive layer CDL5 at least in the bending area BA.

In concluding the detailed description, those skilled in the art will appreciate that many variations and modifications can be made to the embodiments without substantially departing from the principles of the present inventive concept. Therefore, the disclosed embodiments of the inventive concept are used in a generic and descriptive sense only and not for purposes of limitation.

What is claimed is:

1. A display device comprising:
a substrate including a main area which includes a display area and an inorganic encapsulation area surrounding the display area, and a sub-area extending from one side of the main area;
a circuit layer including a semiconductor layer, a plurality of conductive layers, and a plurality of insulating layers disposed between the semiconductive layer and the plurality of conductive layers, respectively;
a light emitting element layer disposed on the circuit layer and including a light emitting element disposed in the display area; and
an encapsulation layer covering the light emitting element layer in the display area and including inorganic encapsulation films and an organic encapsulation film disposed between the inorganic encapsulation films,
wherein the circuit layer includes a first line extending from the sub-area to the display area through the inorganic encapsulation area, and
wherein, the first line is covered by an inorganic insulating layer which constitutes the circuit layer.

2. The display device of claim 1, further comprising:
a dam disposed in a dam area disposed between the display area and the inorganic encapsulation area, and including a planarization film disposed on the first line; and
a bank disposed in a bank area outside the inorganic encapsulation area and including the planarization film disposed on the first line.

3. The display device of claim 2, wherein the first line includes:
a first sub-line disposed in the inorganic encapsulation area;
a second sub-line disposed in the dam area and connected to one end of the first sub-line; and
a third sub-line disposed in the bank area and connected to the other end of the first sub-line.

4. The display device of claim 3, wherein the first sub-line extends from the dam area to the bank area and is connected to the second sub-line in the dam area and the third sub-line in the bank area.

5. The display device of claim 4, wherein, the first line includes a first line layer, a second line layer and a third line layer overlapping each other in a plan view.

6. The display device of claim 5, wherein the first line layer, the second line layer, and the third line layer are electrically connected to each other through the second sub-line and the third sub-line.

7. The display device of claim 5, wherein the first line layer is in direct contact with at least one of the second line layer and the third line layer.

8. The display device of claim 3, wherein the plurality of conductive layers include a bottom conductive layer disposed between the substrate and the semiconductor layer and a buffer film disposed between the bottom conductive layer and the semiconductor layer, and
wherein, the first line further includes a fourth line layer disposed on a same plane as the bottom conductive layer.

9. The display device of claim 8, wherein the first line layer and the fourth line layer are electrically connected to each other through the second sub-line and the third sub-line.

10. The display device of claim 1, wherein the circuit layer further includes a pixel circuit disposed in the display area and connected to the light emitting element, and
wherein the pixel circuit includes:
a first thin film transistor including a first active layer and a first gate electrode;
a second thin film transistor including a second active layer disposed on the first active layer on the first gate electrode and including a semiconductor material different from that of the first active layer, and a second gate electrode; and
a capacitor including a capacitor electrode.

11. The display device of claim 10, further comprising a pixel including the pixel circuit and the light emitting element,
wherein the first line is a power line supplying a first pixel power voltage, a second pixel power voltage, or a bias voltage to the pixel.

12. The display device of claim 11, wherein the circuit layer further includes a second line extending from the sub-area to the display area through the inorganic encapsulation area and spaced apart from the first line, and
wherein, in the inorganic encapsulation area, the second line is formed as a single-layer line and is disposed on a same layer as the second gate electrode.

13. The display device of claim 12, wherein the second line is a power line supplying an initialization voltage to the pixel.

14. The display device of claim 13, wherein the circuit layer further includes a third line extending from the sub-area to the display area through the inorganic encapsulation area and supplying a driving signal to the pixel, and
wherein the third line is disposed on a same layer as the first gate electrode or a bottom conductive layer disposed between the substrate and the semiconductor layer, and extending across the inorganic encapsulation area to overlap the second line.

15. A display device comprising:
a substrate including a main area including a display area in which a pixel is disposed and an inorganic encapsulation area surrounding the display area, and a sub-area extending from one side of the main area;
a circuit layer disposed on the substrate and including a pixel circuit of the pixel and a first power line connected to the pixel and extending from the sub-area to the display area through the inorganic encapsulation area;
a light emitting element layer disposed on the circuit layer in the display area and including a light emitting element of the pixel; and
an encapsulation layer including inorganic encapsulation films disposed to overlap each other in the display area to cover the light emitting element layer and directly connected to each other in the inorganic encapsulation area, and an organic encapsulation film interposed between the inorganic encapsulation films in the display area,
wherein the first power line is covered by at least one inorganic insulating film which constitutes the circuit layer.

16. The display device of claim 15, wherein the circuit layer includes a semiconductor layer, a plurality of conductive layers and a plurality of insulating films disposed on the substrate, and
wherein the pixel circuit includes:
a first thin film transistor including a first active layer and a first gate electrode; and
a second thin film transistor including a second active layer and a second gate electrode.

17. The display device of claim 16, wherein, in the inorganic encapsulation area, the first power line includes a first line layer disposed on a same plane as the second gate electrode.

18. The display device of claim 17, wherein, in the inorganic encapsulation area, the first power line further includes at least one of a second line layer disposed below the first line layer and a third line layer disposed below the second line layer.

19. The display device of claim 18, wherein the circuit layer further includes a second power line connected to the pixel and extending from the sub-area to the display area through the inorganic encapsulation area, and
wherein, in the inorganic encapsulation area, the second power line is formed as a single-layer line disposed on the same layer as the second gate electrode.

20. The display device of claim 17, wherein the circuit layer further includes a bottom conductive layer disposed between the substrate and the semiconductor layer and a buffer film disposed between the bottom conductive layer and the semiconductor layer, and
wherein, in the inorganic encapsulation area, the first power line further includes a fourth line layer disposed on a same plane as the bottom conductive layer.
